(19) United States
(12) Patent Application Publication
(10) Pub. No.: US 2026/0088790 A1
(43) Pub. Date: Mar. 26, 2026

(54) DYNAMIC EQUALIZATION FOR POWER MANAGEMENT

(71) Applicant: Sonos, Inc., Goleta, CA (US)

(72) Inventor: Aurelio Ramos, Boston, MA (US)

(21) Appl. No.: 19/328,533

(22) Filed: Sep. 15, 2025

Related U.S. Application Data
(60) Provisional application No. 63/699,553, filed on Sep. 26, 2024.

(51) Int. Cl. H03G 5/16; G06F 1/3212; G06F 3/16; H03G 5/00

(52) U.S. Cl. CPC H03G 5/165; G06F 1/3212; G06F 3/162; G06F 3/165; G06F 3/167; H03G 5/005

(57) ABSTRACT

A system to provide dynamic equalization for power management. In some embodiments, the system comprises a powered communication port configured to receive audio data and line power, and one or more amplifiers configured to drive one or more speakers. The one or more amplifiers have a peak power consumption that exceeds the maximum power of the line power. The system also comprises power supply circuitry, including at least one capacitor, and an equalizer. The equalizer is configured to generate equalized audio data by: performing a first attenuation on a spectral region of the audio data based on an estimated power budget; applying a temporary second attenuation (e.g., a volume reduction) based on the capacitor voltage; applying a first gain to reverse a portion of the volume reduction over a first time period; and applying a second gain to reverse a remainder of the volume reduction over a second time period.

### CROSS-REFERENCE TO RELATED APPLICATIONS

This application claims priority under 35 U.S.C. § 119(e), to co-pending U.S. Provisional Application No. 63/699,553 filed Sep. 26, 2024, titled DYNAMIC EQUALIZATION FOR POWER MANAGEMENT, which is hereby incorporated herein by reference in its entirety.

### FIELD OF THE DISCLOSURE

The present disclosure is related to consumer goods and, more particularly, to methods, systems, products, features, services, and other elements directed to media playback or some aspect thereof.

### BACKGROUND

Options for accessing and listening to digital audio in an out-loud setting were limited until in 2002, when Sonos, Inc. began development of a new type of playback system. Sonos then filed one of its first patent applications in 2003, entitled “Method for Synchronizing Audio Playback between Multiple Networked Devices,” and began offering its first media playback systems for sale in 2005. The SONOS Wireless Home Sound System enables people to experience music from many sources via one or more networked playback devices. Through a software control application installed on a controller (e.g., smartphone, tablet, computer, voice input device), one can play what she wants in any room having a networked playback device. Media content (e.g., songs, podcasts, video sound) can be streamed to playback devices such that each room with a playback device can play back corresponding different media content. In addition, rooms can be grouped together for synchronous playback of the same media content, and/or the same media content can be heard in all rooms synchronously.

### BRIEF DESCRIPTION OF THE DRAWINGS

Features, aspects, and advantages of the presently disclosed technology may be better understood with regard to the following description, appended claims, and accompanying drawings, as listed below. A person skilled in the relevant art will understand that the features shown in the drawings are for purposes of illustrations, and variations, including different and/or additional features and arrangements thereof, are possible.

FIG. 1A is a partial cutaway view of an environment having a media playback system configured in accordance with aspects of the disclosed technology.

FIG. 1B is a schematic diagram of the media playback system of FIG. 1A and one or more networks.

FIG. 1C is a block diagram of a playback device.

FIG. 1D is a block diagram of a playback device.

FIG. 1E is a block diagram of a bonded playback device.

FIG. 1F is a block diagram of a network microphone device.

FIG. 1G is a block diagram of a playback device.

FIG. 1H is a partial schematic diagram of a control device.

FIGS. 1I through 1L are schematic diagrams of corresponding media playback system zones.

FIG. 1M is a schematic diagram of media playback system areas.

FIG. 2A is a front isometric view of a playback device configured in accordance with aspects of the disclosed technology.

FIG. 2B is a front isometric view of the playback device of FIG. 2A without a grille.

FIG. 2C is an exploded view of the playback device of FIG. 2A.

FIG. 3A is a front view of a network microphone device configured in accordance with aspects of the disclosed technology.

FIG. 3B is a side isometric view of the network microphone device of FIG. 3A.

FIG. 3C is an exploded view of the network microphone device of FIGS. 3A and 3B.

FIG. 3D is an enlarged view of a portion of FIG. 3B.

FIG. 3E is a block diagram of the network microphone device of FIGS. 3A-3D.

FIG. 3F is a schematic diagram of an example voice input.

FIGS. 4A-4D are schematic diagrams of a control device in various stages of operation in accordance with aspects of the disclosed technology.

FIG. 5 is a front view of a control device.

FIG. 6 is a message flow diagram of a media playback system.

FIG. 7A is a block diagram of an example playback device.

FIG. 7B is a block diagram of another example playback device.

FIG. 8 is a block diagram of an example dynamic equalizer.

FIG. 9 is a block diagram of an example filter stage.

FIG. 10 is a block diagram of another example filter stage.

FIG. 11 is a graph illustrating attenuation and piecewise recovery.

FIG. 12 is a flowchart illustrating an example method for employing dynamic equalization for power management of a playback device.

The drawings are for the purpose of illustrating example embodiments, but those of ordinary skill in the art will understand that the technology disclosed herein is not limited to the arrangements and/or instrumentality shown in the drawings.

### DETAILED DESCRIPTION

### I. Overview

SONOS, Inc. has a long history of innovating in the wireless audio space as demonstrated by the successful launch of numerous wireless audio products including, for example, SONOS ROAM, SONOS MOVE, SONOS ERA 100, SONOS ERA 300, SONOS FIVE, SONOS RAY, SONOS BEAM, SONOS ARC, SONOS PORT, and SONOS AMP. In some environments however, particularly in a commercial setting, users may prefer a hardwired application in which numerous audio playback devices are installed at various locations and cables are run to each device to provide power and network connectivity. In these applications, the installation process may be greatly simplified by employing Power over Ethernet (POE), in which a single cable can provide both power and network connectivity.

Audio playback devices in the consumer audio space are typically powered by an alternating current (AC) power source such as a power cord providing 110 volt-230 volt AC power. Many businesses, including bars, restaurants, entertainment venues, and warehouses, occupy relatively large commercial or industrial spaces in which they may wish to provide audio. Typically, commercial establishments mount audio playback devices to walls and/or ceilings and run both Ethernet and AC power to each of the playback devices. Accordingly, it would be advantageous to add support for PoE (or an equivalent) to playback devices so that only one Ethernet cable needs to be run to each playback device instead of both an Ethernet cable and a separate power cable. As such, adding PoE support can lower the barrier to deploying a large number of playback devices in a commercial setting.

However, such an arrangement has various drawbacks. For example, a playback device may have significant peak power demands during certain playback situations (e.g., at higher volume for certain audio tracks) that considerably exceed the capabilities of many PoE systems. For instance, the peak power demand of an audio playback device may be 120 watts while the most common PoE types (PoE and PoE+) only support up to 15 to 30 watts (e.g., PoE supports up to approximately 15 watts and PoE+ supports up to approximately 30 watts). Accordingly, a typical PoE design that may be suitable for devices with relatively consistent power demands could result in undesirable audio distortion during audio playback.

One technique for addressing this problem is to simply limit the playback volume to a sufficiently low level that ensures the playback device would never exceed the power delivery capabilities of the PoE system. This straightforward and conservative approach, however, would not be consistent with the desire to provide a high quality listening experience, as the volume would generally be too low. Additionally, there is a difference between the theoretical power limit specified for the PoE system and the actual power limit. This difference results from a number of factors including, for example, the impedance of the Ethernet cables and the length of those cables. Thus, the amount of power that the playback device can actually draw is typically less than the specified value and can vary based on the installation. This approach would therefore need to further discount the available power resulting in additional volume reduction and a poorer listening experience.

A better technique would be to dynamically filter the audio signal to reduce the energy required to reproduce the signal. In some examples, a two stage approach may be employed for energy reduction. In one stage, lower frequencies of the signal may be filtered based on an estimated power budget. In a second stage, the gain of the audio signal may be reduced (e.g., over the entire frequency range of the signal) as needed for relatively brief periods, followed by a piecewise gain recovery period designed to mitigate the audible impact of the gain reduction.

To this end, embodiments described herein relate to dynamic equalization in which a portion of the audio spectrum associated with the greatest power consumption is filtered over relatively longer time periods. The dynamic equalization also includes adjusting the overall audio gain, as needed, over shorter time periods. In some examples, application of the dynamic equalization is based on a number of factors including an estimated power budget, measured and predicted voltage of a power supply capacitor, predicted energy requirements of the segment of the audio signal being played, and knowledge of the electroacoustic characteristics of the amplifier and speaker of the playback device.

In some embodiments, for example, a playback device can include at least one powered communication port configured to receive audio data and line power. The playback device can also include one or more amplifiers configured to drive one or more speakers. The one or more amplifiers may have a peak power consumption that is greater than a maximum power of the line power. The playback device may also include power supply circuitry comprising at least one capacitor. The playback device may further include an equalizer configured to generate equalized audio data by: (1) performing a first attenuation on a spectral region of the audio data based on an estimated power budget; (2) applying a temporary second attenuation over a broad frequency (e.g., a volume reduction) based on the voltage of the at least one capacitor; (3) applying a first gain to reverse a portion of the volume reduction over a first time period; and (4) applying a second gain to reverse a remainder of the volume reduction over a second time period subsequent to the first time period. In addition, the playback device may include at least one processor and at least one non-transitory computer-readable medium comprising program instructions that are executable by the at least one processor such that the playback device is configured to drive the one or more amplifiers to play back at least a portion of the equalized audio data.

In some embodiments, the playback device may be implemented as a stationary playback device that requires a connection to an external power source (e.g., a POE injector, a USB adapter, etc.) in order to play back an audio track. For instance, the stationary playback device may not be configured to use any internal energy storage device(s) (e.g., a battery) to play back an audio track when not connected to an external power source.

In some embodiments, the playback device may not be configured to directly receive mains AC power (e.g., AC power from a wall outlet between 110 and 230 volts) as a power input. For instance, the playback device may only receive power through other power sources separate and apart from mains AC power such as one or more of the following: PoE power sources, USB power sources, and/or wireless power sources such as QI wireless transmitters.

While some examples described herein may refer to functions performed by given actors such as “users,” “listeners,” and/or other entities, it should be understood that such references are for purposes of explanation only. The claims should not be interpreted to require action by any such example actor unless explicitly required by the language of the claims themselves.

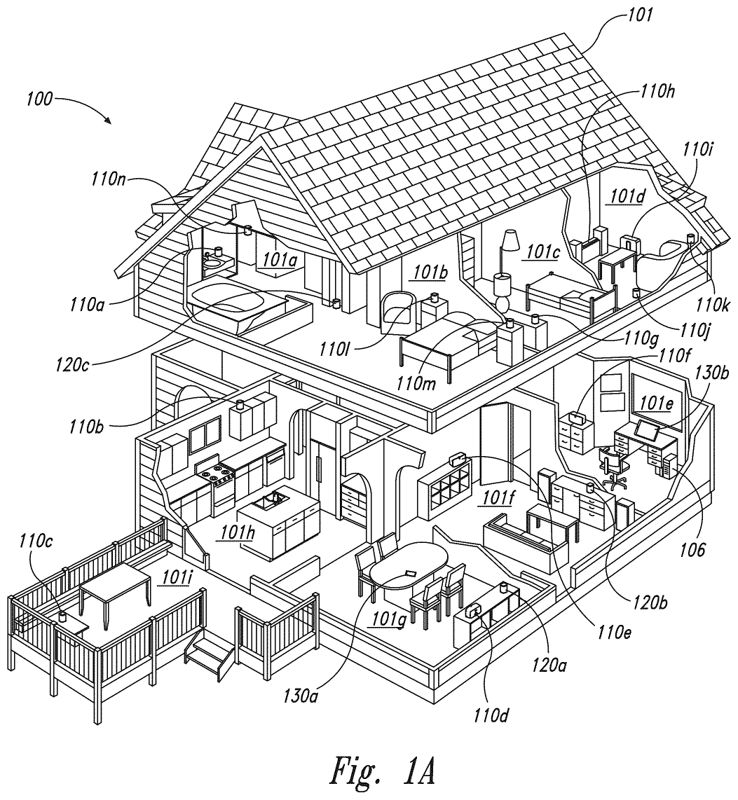

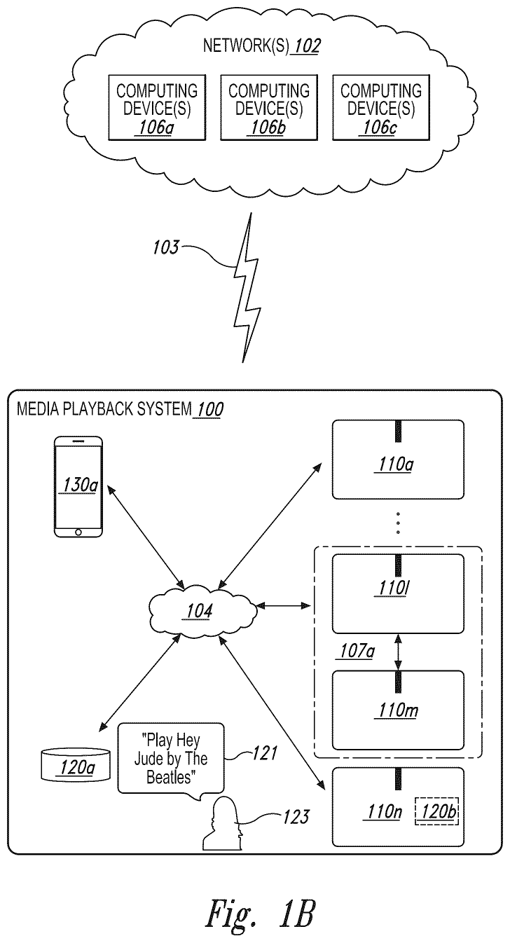

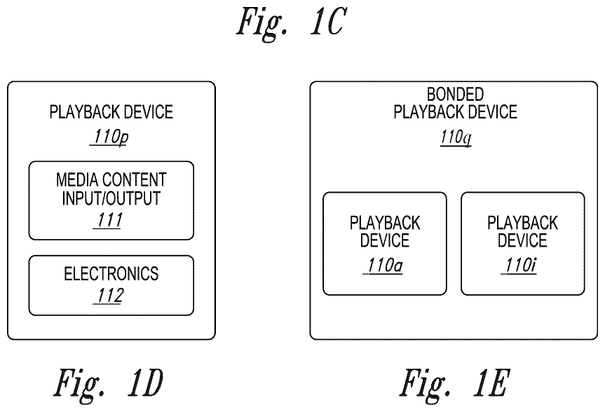

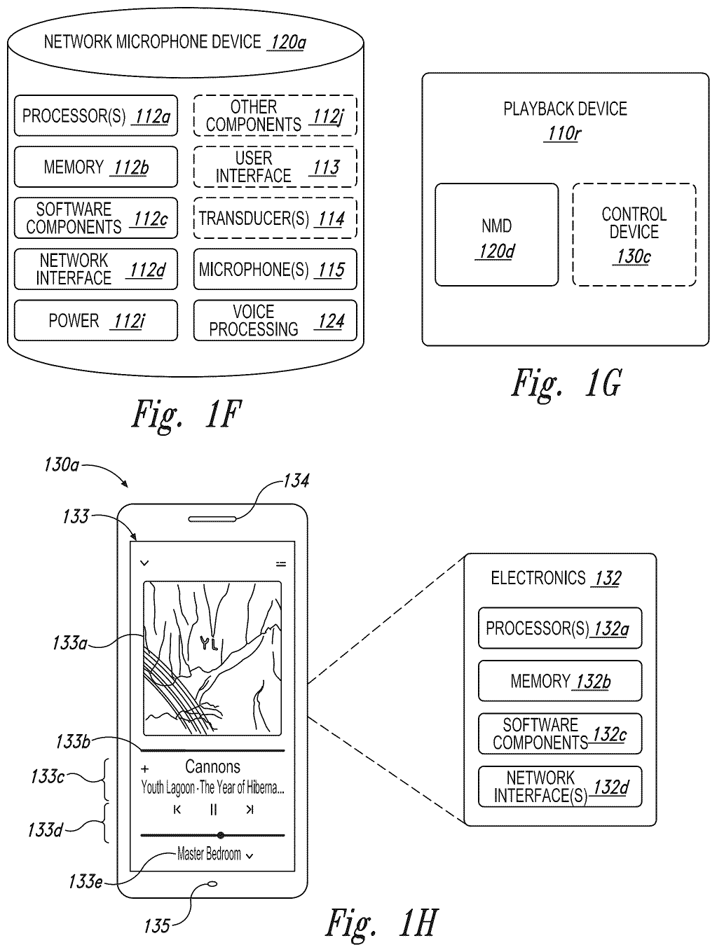

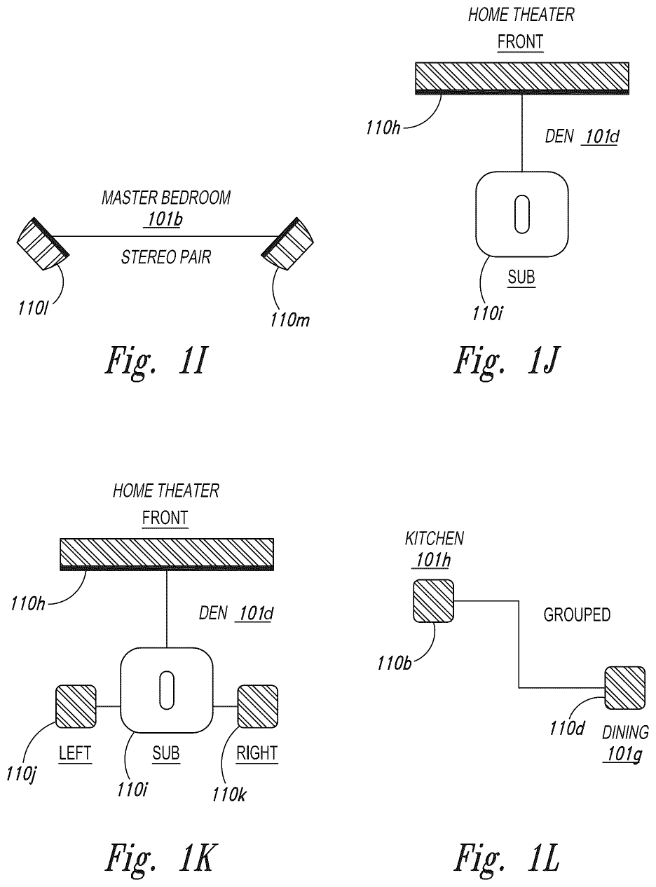

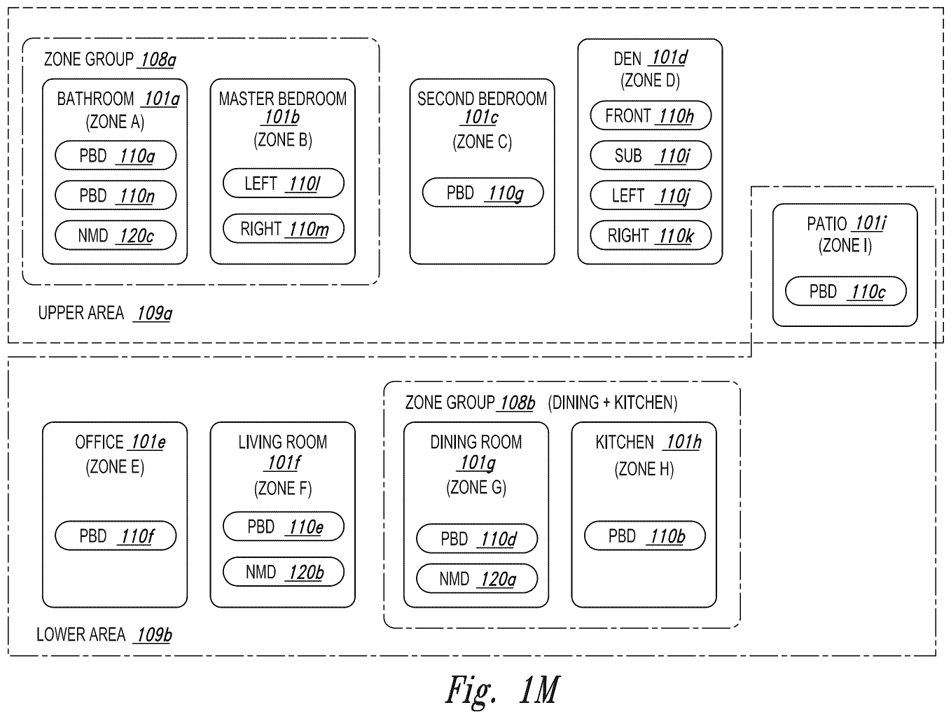

In the Figures, identical reference numbers identify generally similar, and/or identical, elements. To facilitate the discussion of any particular element, the most significant digit or digits of a reference number refers to the Figure in which that element is first introduced. For example, element 110a is first introduced and discussed with reference to FIG. 1A. Many of the details, dimensions, angles, and other features shown in the Figures are merely illustrative of particular embodiments of the disclosed technology. Accordingly, other embodiments can have other details, dimensions, angles, and features without departing from the spirit or scope of the disclosure. In addition, those of ordinary skill in the art will appreciate that further embodiments of the various disclosed technologies can be practiced without several of the details described below.

### II. Suitable Operating Environment

FIG. 1A is a partial cutaway view of a media playback system 100 distributed in an environment 101 (e.g., a house). The media playback system 100 comprises one or more playback devices 110 (identified individually as playback devices 110a-n), one or more network microphone devices 120 (“NMDs”) (identified individually as NMDs 120a-c), and one or more control devices 130 (identified individually as control devices 130a and 130b).

As used herein the term “playback device” can generally refer to a network device configured to receive, process, and output data of a media playback system. For example, a playback device can be a network device that receives and processes audio content. In some embodiments, a playback device includes one or more transducers or speakers powered by one or more amplifiers. In other embodiments, however, a playback device includes one of (or neither of) the speaker and the amplifier. For instance, a playback device can comprise one or more amplifiers configured to drive one or more speakers external to the playback device via a corresponding wire or cable.

Moreover, as used herein the term “NMD” (i.e., a “network microphone device”) can generally refer to a network device that is configured for audio detection. In some embodiments, an NMD is a stand-alone device configured primarily for audio detection. In other embodiments, an NMD is incorporated into a playback device (or vice versa).

The term “control device” can generally refer to a network device configured to perform functions relevant to facilitating user access, control, and/or configuration of the media playback system 100.

Each of the playback devices 110 is configured to receive audio signals or data from one or more media sources (e.g., one or more remote servers, one or more local devices, etc.) and play back the received audio signals or data as sound. The one or more NMDs 120 are configured to receive spoken word commands, and the one or more control devices 130 are configured to receive user input. In response to the received spoken word commands and/or user input, the media playback system 100 can play back audio via one or more of the playback devices 110. In certain embodiments, the playback devices 110 are configured to commence playback of media content in response to a trigger. For instance, one or more of the playback devices 110 can be configured to play back a morning playlist upon detection of an associated trigger condition (e.g., presence of a user in a kitchen, detection of a coffee machine operation, etc.). In some embodiments, for example, the media playback system 100 is configured to play back audio from a first playback device (e.g., the playback device 110a) in synchrony with a second playback device (e.g., the playback device 110b). Interactions between the playback devices 110, NMDs 120, and/or control devices 130 of the media playback system 100 configured in accordance with the various embodiments of the disclosure are described in greater detail below with respect to FIGS. 1B-6.

In the illustrated embodiment of FIG. 1A, the environment 101 comprises a household having several rooms, spaces, and/or playback zones, including (clockwise from upper left) a master bathroom 101a, a master bedroom 101b, a second bedroom 101c, a family room or den 101d, an office 101e, a living room 101f, a dining room 101g, a kitchen 101h, and an outdoor patio 101i. While certain embodiments and examples are described below in the context of a home environment, the technologies described herein may be implemented in other types of environments. In some embodiments, for example, the media playback system 100 can be implemented in one or more commercial settings (e.g., a restaurant, mall, airport, hotel, a retail or other store), one or more vehicles (e.g., a sports utility vehicle, bus, car, a ship, a boat, an airplane, etc.), multiple environments (e.g., a combination of home and vehicle environments), and/or another suitable environment where multi-zone audio may be desirable.

The media playback system 100 can comprise one or more playback zones, some of which may correspond to the rooms in the environment 101. The media playback system 100 can be established with one or more playback zones, after which additional zones may be added, or removed, to form, for example, the configuration shown in FIG. 1A. Each zone may be given a name according to a different room or space such as the office 101e, master bathroom 101a, master bedroom 101b, the second bedroom 101c, kitchen 101h, dining room 101g, living room 101f, and/or the balcony 101i. In some aspects, a single playback zone may include multiple rooms or spaces. In certain aspects, a single room or space may include multiple playback zones.

In the illustrated embodiment of FIG. 1A, the second bedroom 101c, the office 101e, the living room 101f, the dining room 101g, the kitchen 101h, and the outdoor patio 101i each include one playback device 110, and the master bathroom 101a, the master bedroom 101b, and the den 101d include a plurality of playback devices 110. In the master bedroom 101b, the playback devices 110l and 110m may be configured, for example, to play back audio content in synchrony as individual ones of playback devices 110, as a bonded playback zone, as a consolidated playback device, and/or any combination thereof. Similarly, in the den 101d, the playback devices 110h-k can be configured, for instance, to play back audio content in synchrony as individual ones of playback devices 110, as one or more bonded playback devices, and/or as one or more consolidated playback devices. Additional details regarding bonded and consolidated playback devices are described below with respect to FIGS. 1B, 1E, and 1I-1M.

In some aspects, one or more of the playback zones in the environment 101 may each be playing different audio content. For instance, a user may be grilling on the patio 101i and listening to hip hop music being played by the playback device 110c while another user is preparing food in the kitchen 101h and listening to classical music played by the playback device 110b. In another example, a playback zone may play the same audio content in synchrony with another playback zone. For instance, the user may be in the office 101e listening to the playback device 110f playing back the same hip hop music being played back by playback device 110c on the patio 101i. In some aspects, the playback devices 110c and 110f play back the hip hop music in synchrony such that the user perceives that the audio content is being played seamlessly (or at least substantially seamlessly) while moving between different playback zones. Additional details regarding audio playback synchronization among playback devices and/or zones can be found, for example, in U.S. Pat. No. 8,234,395 entitled, “System and method for synchronizing operations among a plurality of independently clocked digital data processing devices,” which is incorporated herein by reference in its entirety.

a. Suitable Media Playback System

FIG. 1B is a schematic diagram of the media playback system 100 and a cloud network 102. For case of illustration, certain devices of the media playback system 100 and the cloud network 102 are omitted from FIG. 1B. One or more communication links 103 (referred to hereinafter as “the links 103”) communicatively couple the media playback system 100 and the cloud network 102.

The links 103 can comprise, for example, one or more wired networks, one or more wireless networks, one or more wide area networks (WAN), one or more local area networks (LAN), one or more personal area networks (PAN), one or more telecommunication networks (e.g., one or more Global System for Mobiles (GSM) networks, Code Division Multiple Access (CDMA) networks, Long-Term Evolution (LTE) networks, 5G communication networks, and/or other suitable data transmission protocol networks), etc. The cloud network 102 is configured to deliver media content (e.g., audio content, video content, photographs, social media content, etc.) to the media playback system 100 in response to a request transmitted from the media playback system 100 via the links 103. In some embodiments, the cloud network 102 is further configured to receive data (e.g., voice input data) from the media playback system 100 and correspondingly transmit commands and/or media content to the media playback system 100.

The cloud network 102 comprises computing devices 106 (identified separately as a first computing device 106a, a second computing device 106b, and a third computing device 106c). The computing devices 106 can comprise individual computers or servers, such as, for example, a media streaming service server storing audio and/or other media content, a voice service server, a social media server, a media playback system control server, etc. In some embodiments, one or more of the computing devices 106 comprise modules of a single computer or server. In certain embodiments, one or more of the computing devices 106 comprise one or more modules, computers, and/or servers. Moreover, while the cloud network 102 is described above in the context of a single cloud network, in some embodiments the cloud network 102 comprises a plurality of cloud networks comprising communicatively coupled computing devices. Furthermore, while the cloud network 102 is shown in FIG. 1B as having three of the computing devices 106, in some embodiments, the cloud network 102 comprises fewer (or more than) three computing devices 106.

The media playback system 100 is configured to receive media content from the networks 102 via the links 103. The received media content can comprise, for example, a Uniform Resource Identifier (URI) and/or a Uniform Resource Locator (URL). For instance, in some examples, the media playback system 100 can stream, download, or otherwise obtain data from a URI or a URL corresponding to the received media content. A network 104 communicatively couples the links 103 and at least a portion of the devices (e.g., one or more of the playback devices 110, NMDs 120, and/or control devices 130) of the media playback system 100. The network 104 can include, for example, a wireless network (e.g., a WI-FI network, a BLUETOOTH network, a Z-WAVE network, a ZIGBEE network, and/or other suitable wireless communication protocol network) and/or a wired network (e.g., a network comprising Ethernet, Universal Serial Bus (USB), and/or another suitable wired communication). As those of ordinary skill in the art will appreciate, as used herein, “WI-FI” can refer to several different communication protocols including, for example, Institute of Electrical and Electronics Engineers (IEEE) 802.11a, 802.11b, 802.11g, 802.11n, 802.11ac, 802.11ac, 802.11ad, 802.11af, 802.11ah, 802.11ai, 802.11aj, 802.11aq, 802.11ax, 802.11ay, 802.15, etc. transmitted at 2.4 Gigahertz (GHz), 5 GHZ, and/or another suitable frequency.

In some embodiments, the network 104 comprises a dedicated communication network that the media playback system 100 uses to transmit messages between individual devices and/or to transmit media content to and from media content sources (e.g., one or more of the computing devices 106). In certain embodiments, the network 104 is configured to be accessible only to devices in the media playback system 100, thereby reducing interference and competition with other household devices. In other embodiments, however, the network 104 comprises an existing household or commercial facility communication network (e.g., a household or commercial facility WI-FI network). In some embodiments, the links 103 and the network 104 comprise one or more of the same networks. In some aspects, for example, the links 103 and the network 104 comprise a telecommunication network (e.g., an LTE network, a 5G network, etc.). Moreover, in some embodiments, the media playback system 100 is implemented without the network 104, and devices comprising the media playback system 100 can communicate with each other, for example, via one or more direct connections, PANs, telecommunication networks, and/or other suitable communication links. The network 104 may be referred to herein as a “local communication network” to differentiate the network 104 from the cloud network 102 that couples the media playback system 100 to remote devices, such as cloud servers that host cloud services.

In some embodiments, audio content sources may be regularly added or removed from the media playback system 100. In some embodiments, for example, the media playback system 100 performs an indexing of media items when one or more media content sources are updated, added to, and/or removed from the media playback system 100. The media playback system 100 can scan identifiable media items in some or all folders and/or directories accessible to the playback devices 110, and generate or update a media content database comprising metadata (e.g., title, artist, album, track length, etc.) and other associated information (e.g., URIs, URLs, etc.) for each identifiable media item found. In some embodiments, for example, the media content database is stored on one or more of the playback devices 110, network microphone devices 120, and/or control devices 130.

In the illustrated embodiment of FIG. 1B, the playback devices 110l and 110m comprise a group 107a. The playback devices 110l and 110m can be positioned in different rooms and be grouped together in the group 107a on a temporary or permanent basis based on user input received at the control device 130a and/or another control device 130 in the media playback system 100. When arranged in the group 107a, the playback devices 110l and 110m can be configured to play back the same or similar audio content in synchrony from one or more audio content sources. In certain embodiments, for example, the group 107a comprises a bonded zone in which the playback devices 110l and 110m comprise left audio and right audio channels, respectively, of multi-channel audio content, thereby producing or enhancing a stereo effect of the audio content. In some embodiments, the group 107a includes additional playback devices 110. In other embodiments, however, the media playback system 100 omits the group 107a and/or other grouped arrangements of the playback devices 110. Additional details regarding groups and other arrangements of playback devices are described in further detail below with respect to FIGS. 1I-1M.

The media playback system 100 includes the NMDs 120a and 120b, each comprising one or more microphones configured to receive voice utterances from a user. In the illustrated embodiment of FIG. 1B, the NMD 120a is a standalone device and the NMD 120b is integrated into the playback device 110n. The NMD 120a, for example, is configured to receive voice input 121 from a user 123. In some embodiments, the NMD 120a transmits data associated with the received voice input 121 to a voice assistant service (VAS) configured to (i) process the received voice input data and (ii) facilitate one or more operations on behalf of the media playback system 100.

In some aspects, for example, the computing device 106c comprises one or more modules and/or servers of a VAS (e.g., a VAS operated by one or more of SONOS, AMAZON, GOOGLE, APPLE, MICROSOFT, etc.). The computing device 106c can receive the voice input data from the NMD 120a via the network 104 and the links 103.

In response to receiving the voice input data, the computing device 106c processes the voice input data (i.e., “Play Hey Jude by The Beatles”), and determines that the processed voice input includes a command to play a song (e.g., “Hey Jude”). In some embodiments, after processing the voice input, the computing device 106c accordingly transmits commands to the media playback system 100 to play back “Hey Jude” by the Beatles from a suitable media service (e.g., via one or more of the computing devices 106) on one or more of the playback devices 110. In other embodiments, the computing device 106c may be configured to interface with media services on behalf of the media playback system 100. In such embodiments, after processing the voice input, instead of the computing device 106c transmitting commands to the media playback system 100 causing the media playback system 100 to retrieve the requested media from a suitable media service, the computing device 106c itself causes a suitable media service to provide the requested media to the media playback system 100 in accordance with the user's voice utterance.

b. Suitable Playback Devices

FIG. 1C is a block diagram of the playback device 110a comprising an input/output 111. The input/output 111 can include an analog I/O 111a (e.g., one or more wires, cables, and/or other suitable communication links configured to carry analog signals) and/or a digital I/O 111b (e.g., one or more wires, cables, or other suitable communication links configured to carry digital signals). In some embodiments, the analog I/O 111a is an audio line-in input connection comprising, for example, an auto-detecting 3.5 mm audio line-in connection. In some embodiments, the digital I/O 111b comprises a Sony/Philips Digital Interface Format (S/PDIF) communication interface and/or cable and/or a Toshiba Link (TOSLINK) cable. In some embodiments, the digital I/O 111b comprises a High-Definition Multimedia Interface (HDMI) interface and/or cable. In some embodiments, the digital I/O 111b includes one or more wireless communication links comprising, for example, a radio frequency (RF), infrared, WI-FI, BLUETOOTH, or another suitable communication link. In certain embodiments, the analog I/O 111a and the digital I/O 111b comprise interfaces (e.g., ports, plugs, jacks, etc.) configured to receive connectors of cables transmitting analog and digital signals, respectively, without necessarily including cables.

The playback device 110a, for example, can receive media content (e.g., audio content comprising music and/or other sounds) from a local audio source 105 via the input/output 111 (e.g., a cable, a wire, a PAN, a BLUETOOTH connection, an ad hoc wired or wireless communication network, and/or another suitable communication link). The local audio source 105 can comprise, for example, a mobile device (e.g., a smartphone, a tablet, a laptop computer, etc.) or another suitable audio component (e.g., a television, a desktop computer, an amplifier, a phonograph (such as an LP turntable), a Blu-ray player, a memory storing digital media files, etc.). In some aspects, the local audio source 105 includes local music libraries on a smartphone, a computer, a networked-attached storage (NAS), and/or another suitable device configured to store media files. In certain embodiments, one or more of the playback devices 110, NMDs 120, and/or control devices 130 comprise the local audio source 105. In other embodiments, however, the media playback system omits the local audio source 105 altogether. In some embodiments, the playback device 110a does not include an input/output 111 and receives all audio content via the network 104.

The playback device 110a further comprises electronics 112, a user interface 113 (e.g., one or more buttons, knobs, dials, touch-sensitive surfaces, displays, touchscreens, etc.), and one or more transducers 114 (referred to hereinafter as “the transducers 114”). The electronics 112 are configured to receive audio from an audio source (e.g., the local audio source 105) via the input/output 111 or one or more of the computing devices 106a-c via the network 104 (FIG. 1B), amplify the received audio, and output the amplified audio for playback via one or more of the transducers 114. In some embodiments, the playback device 110a optionally includes one or more microphones 115 (e.g., a single microphone, a plurality of microphones, a microphone array) (hereinafter referred to as “the microphones 115”). In certain embodiments, for example, the playback device 110a having one or more of the optional microphones 115 can operate as an NMD configured to receive voice input from a user and correspondingly perform one or more operations based on the received voice input.

In the illustrated embodiment of FIG. 1C, the electronics 112 comprise one or more processors 112a (referred to hereinafter as “the processors 112a”), memory 112b, software components 112c, a network interface 112d, one or more audio processing components 112g (referred to hereinafter as “the audio components 112g”), one or more audio amplifiers 112h (referred to hereinafter as “the amplifiers 112h”), and power 112i (e.g., one or more power supplies, power cables, power receptacles, batteries, induction coils, Power-over Ethernet (POE) interfaces, and/or other suitable sources of electric power). In some embodiments, the electronics 112 optionally include one or more other components 112j (e.g., one or more sensors, video displays, touchscreens, battery charging bases, etc.).

The processors 112a can comprise clock-driven computing component(s) configured to process data, and the memory 112b can comprise a computer-readable medium (e.g., a tangible, non-transitory computer-readable medium loaded with one or more of the software components 112c) configured to store instructions for performing various operations and/or functions. The processors 112a are configured to execute the instructions stored on the memory 112b to perform one or more of the operations. The operations can include, for example, causing the playback device 110a to retrieve audio data from an audio source (e.g., one or more of the computing devices 106a-c (FIG. 1B)), and/or another one of the playback devices 110. In some embodiments, the operations further include causing the playback device 110a to send audio data to another one of the playback devices 110a and/or another device (e.g., one of the NMDs 120). Certain embodiments include operations causing the playback device 110a to pair with another of the one or more playback devices 110 to enable a multi-channel audio environment (e.g., a stereo pair, a bonded zone, etc.).

The processors 112a can be further configured to perform operations causing the playback device 110a to synchronize playback of audio content with another of the one or more playback devices 110. As those of ordinary skill in the art will appreciate, during synchronous playback of audio content on a plurality of playback devices, a listener will preferably be unable to perceive time-delay differences between playback of the audio content by the playback device 110a and the other one or more other playback devices 110. Additional details regarding audio playback synchronization among playback devices can be found, for example, in U.S. Pat. No. 8,234,395, which was incorporated by reference above.

In some embodiments, the memory 112b is further configured to store data associated with the playback device 110a, such as one or more zones and/or zone groups of which the playback device 110a is a member, audio sources accessible to the playback device 110a, and/or a playback queue that the playback device 110a (and/or another of the one or more playback devices) can be associated with. The stored data can comprise one or more state variables that are periodically updated and used to describe a state of the playback device 110a. The memory 112b can also include data associated with a state of one or more of the other devices (e.g., the playback devices 110, NMDs 120, control devices 130) of the media playback system 100. In some aspects, for example, the state data is shared during predetermined intervals of time (e.g., every 5 seconds, every 10 seconds, every 60 seconds, etc.) among at least a portion of the devices of the media playback system 100, so that one or more of the devices have the most recent data associated with the media playback system 100.

The network interface 112d is configured to facilitate a transmission of data between the playback device 110a and one or more other devices on a data network such as, for example, the links 103 and/or the network 104 (FIG. 1B). The network interface 112d is configured to transmit and receive data corresponding to media content (e.g., audio content, video content, text, photographs) and other signals (e.g., non-transitory signals) comprising digital packet data including an Internet Protocol (IP)-based source address and/or an IP-based destination address. The network interface 112d can parse the digital packet data such that the electronics 112 properly receive and process the data destined for the playback device 110a.

In the illustrated embodiment of FIG. 1C, the network interface 112d comprises one or more wireless interfaces 112e (referred to hereinafter as “the wireless interface 112e”). The wireless interface 112e (e.g., a suitable interface comprising one or more antennae) can be configured to wirelessly communicate with one or more other devices (e.g., one or more of the other playback devices 110, NMDs 120, and/or control devices 130) that are communicatively coupled to the network 104 (FIG. 1B) in accordance with a suitable wireless communication protocol (e.g., WI-FI, BLUETOOTH, LTE, etc.). In some embodiments, the network interface 112d optionally includes a wired interface 112f (e.g., an interface or receptacle configured to receive a network cable such as an Ethernet, a USB-A, USB-C, and/or Thunderbolt cable) configured to communicate over a wired connection with other devices in accordance with a suitable wired communication protocol. In certain embodiments, the network interface 112d includes the wired interface 112f and excludes the wireless interface 112e. In some embodiments, the electronics 112 exclude the network interface 112d altogether and transmit and receive media content and/or other data via another communication path (e.g., the input/output 111).

The audio components 112g are configured to process and/or filter data comprising media content received by the electronics 112 (e.g., via the input/output 111 and/or the network interface 112d) to produce output audio signals. In some embodiments, the audio processing components 112g comprise, for example, one or more digital-to-analog converters (DACs), audio preprocessing components, audio enhancement components, digital signal processors (DSPs), and/or other suitable audio processing components, modules, circuits, etc. In certain embodiments, one or more of the audio processing components 112g can comprise one or more subcomponents of the processors 112a. In some embodiments, the electronics 112 omit the audio processing components 112g. In some aspects, for example, the processors 112a execute instructions stored on the memory 112b to perform audio processing operations to produce the output audio signals.

The amplifiers 112h are configured to receive and amplify the audio output signals produced by the audio processing components 112g and/or the processors 112a. The amplifiers 112h can comprise electronic devices and/or components configured to amplify audio signals to levels sufficient for driving one or more of the transducers 114. In some embodiments, for example, the amplifiers 112h include one or more switching or class-D power amplifiers. In other embodiments, however, the amplifiers 112h include one or more other types of power amplifiers (e.g., linear gain power amplifiers, class-A amplifiers, class-B amplifiers, class-AB amplifiers, class-C amplifiers, class-D amplifiers, class-E amplifiers, class-F amplifiers, class-G amplifiers, class H amplifiers, and/or another suitable type of power amplifier). In certain embodiments, the amplifiers 112h comprise a suitable combination of two or more of the foregoing types of power amplifiers. Moreover, in some embodiments, individual ones of the amplifiers 112h correspond to individual ones of the transducers 114. In other embodiments, however, the electronics 112 include a single one of the amplifiers 112h configured to output amplified audio signals to a plurality of the transducers 114. In some other embodiments, the electronics 112 omit the amplifiers 112h.

The transducers 114 (e.g., one or more speakers and/or speaker drivers) receive the amplified audio signals from the amplifier 112h and render or output the amplified audio signals as sound (e.g., audible sound waves having a frequency between about 20 Hertz (Hz) and 20 kilohertz (kHz)). In some embodiments, the transducers 114 can comprise a single transducer. In other embodiments, however, the transducers 114 comprise a plurality of audio transducers. In some embodiments, the transducers 114 comprise more than one type of transducer. For example, the transducers 114 can include one or more low frequency transducers (e.g., subwoofers, woofers), mid-range frequency transducers (e.g., mid-range transducers, mid-woofers), and one or more high frequency transducers (e.g., one or more tweeters). As used herein, “low frequency” can generally refer to audible frequencies below about 500 Hz, “mid-range frequency” can generally refer to audible frequencies between about 500 Hz and about 2 kHz, and “high frequency” can generally refer to audible frequencies above 2 kHz. In certain embodiments, however, one or more of the transducers 114 comprise transducers that do not adhere to the foregoing frequency ranges. For example, one of the transducers 114 may comprise a mid-woofer transducer configured to output sound at frequencies between about 200 Hz and about 5 kHz.

By way of illustration, Sonos, Inc. presently offers (or has offered) for sale certain playback devices including, for example, a “SONOS ONE,” “PLAY:1,” “PLAY:3,” “PLAY:5,” “PLAYBAR,” “PLAYBASE,” “CONNECT:AMP,” “CONNECT,” “AMP,” “PORT,” and “SUB.” Other suitable playback devices may additionally or alternatively be used to implement the playback devices of example embodiments disclosed herein. Additionally, one of ordinary skill in the art will appreciate that a playback device is not limited to the examples described herein or to Sonos product offerings. In some embodiments, for example, one or more playback devices 110 comprise wired or wireless headphones (e.g., over-the-ear headphones, on-ear headphones, in-ear earphones, etc.). In other embodiments, one or more of the playback devices 110 comprise a docking station and/or an interface configured to interact with a docking station for personal mobile media playback devices. In certain embodiments, a playback device may be integral to another device or component such as a television, an LP turntable, a lighting fixture, or some other device for indoor or outdoor use. In some embodiments, a playback device omits a user interface and/or one or more transducers. For example, FIG. 1D is a block diagram of a playback device 110p comprising the input/output 111 and electronics 112 without the user interface 113 or transducers 114.

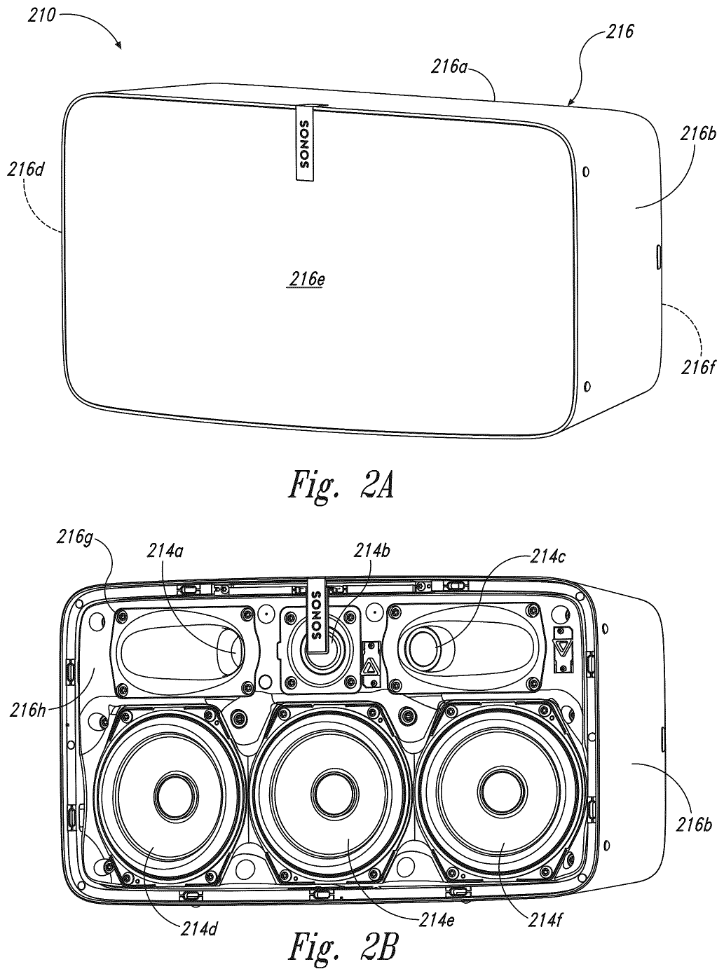

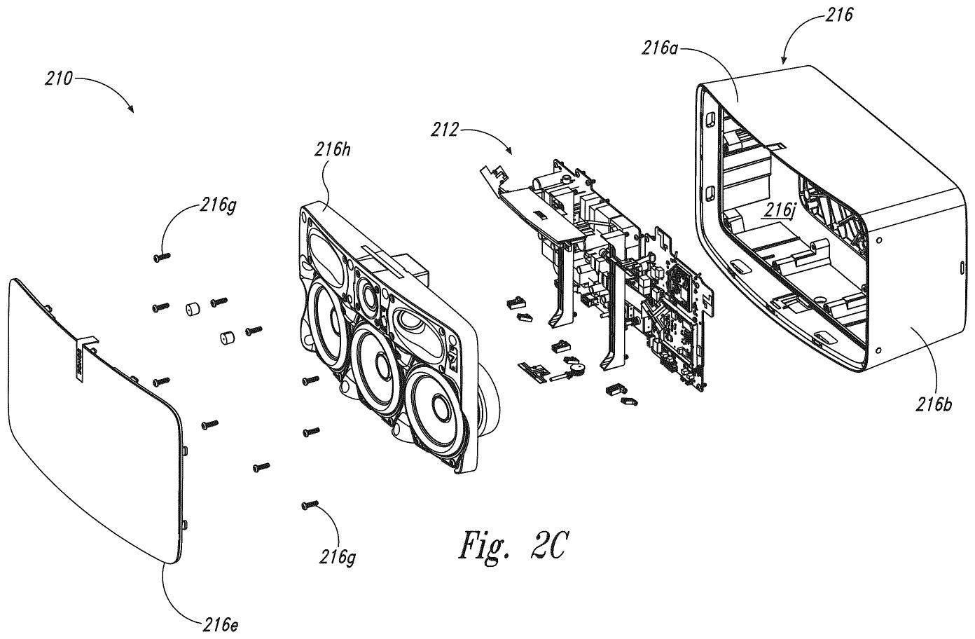

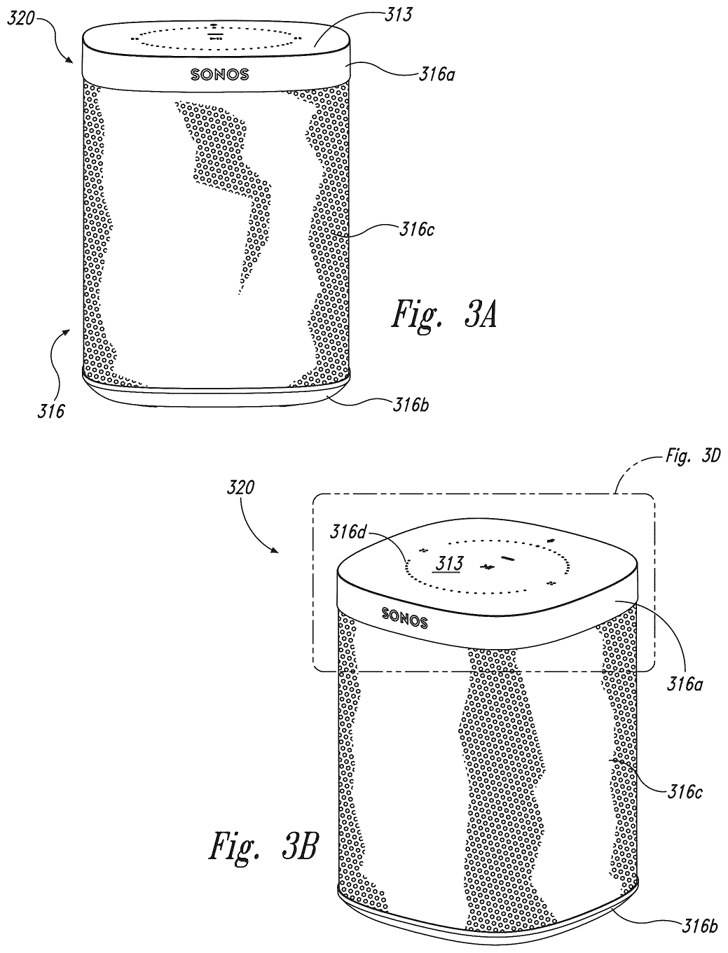

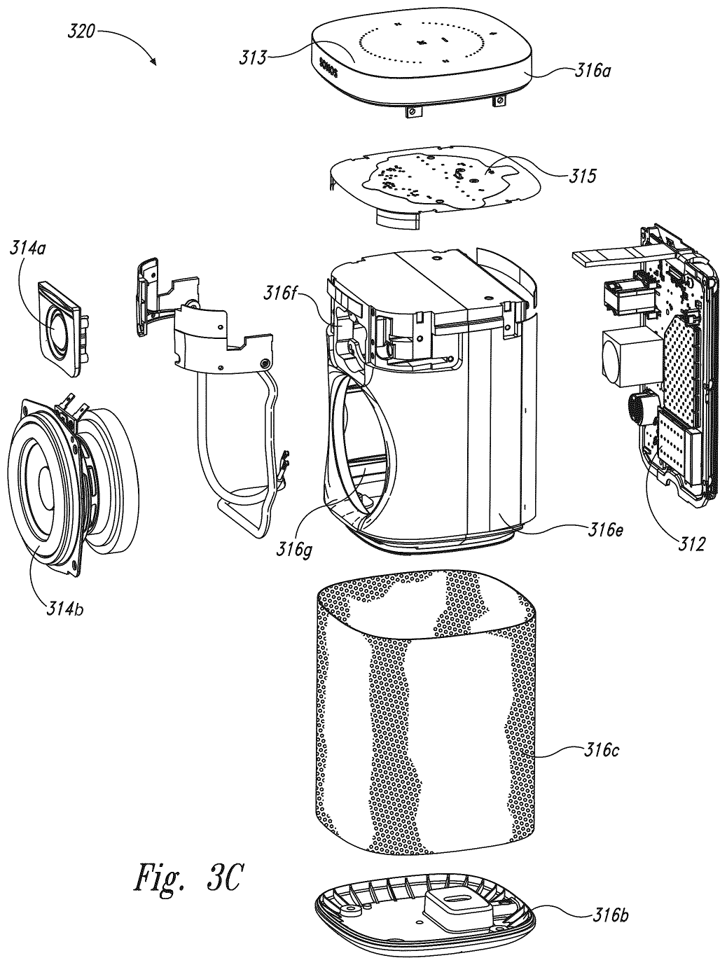

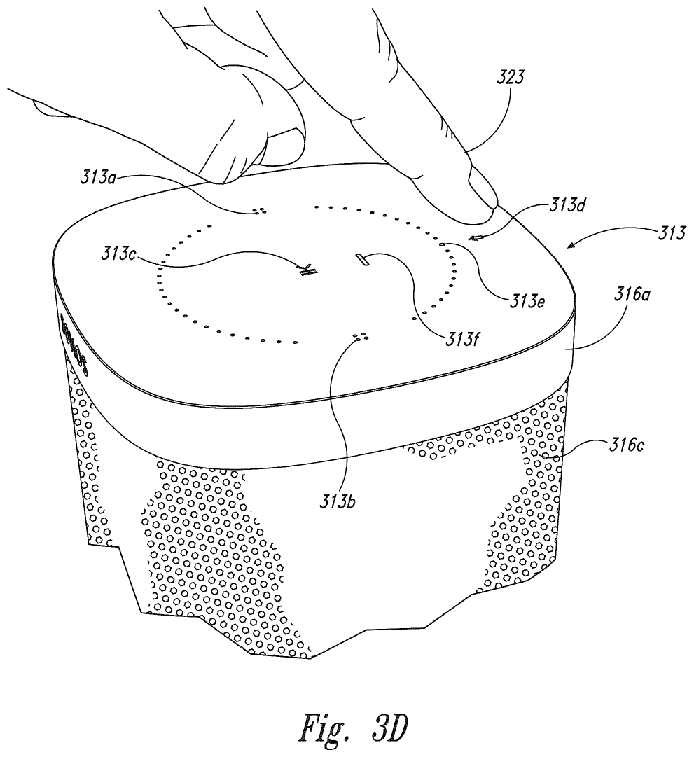

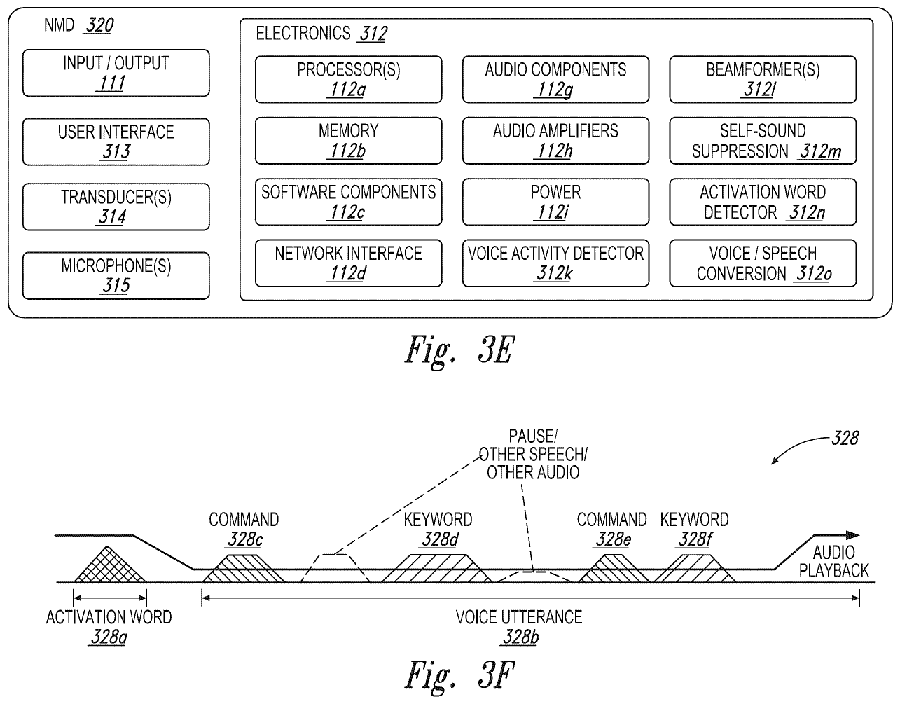

FIG. 1E is a block diagram of a bonded playback device 110q comprising the playback device 110a (FIG. 1C) sonically bonded with the playback device 110i (e.g., a subwoofer) (FIG. 1A). In the illustrated embodiment, the playback devices 110a and 110i are separate ones of the playback devices 110 housed in separate enclosures. In some embodiments, however, the bonded playback device 110q comprises a single enclosure housing both the playback devices 110a and 110i. The bonded playback device 110q can be configured to process and reproduce sound differently than an unbonded playback device (e.g., the playback device 110a of FIG. 1C) and/or paired or bonded playback devices (e.g., the playback devices 110l and 110m of FIG. 1B). In some embodiments, for example, the playback device 110a is a full-range playback device configured to render low frequency, mid-range frequency, and high frequency audio content, and the playback device 110i is a subwoofer configured to render low frequency audio content. In some aspects, the playback device 110a, when bonded with the first playback device, is configured to render only the mid-range and high frequency components of a particular audio content, while the playback device 110i renders the low frequency component of the particular audio content. In some embodiments, the bonded playback device 110q includes additional playback devices and/or another bonded playback device. Additional playback device embodiments are described in further detail below with respect to FIGS. 2A-3D.”

c. Suitable Network Microphone Devices (NMDs)

FIG. 1F is a block diagram of the NMD 120a (FIGS. 1A and 1B). The NMD 120a includes one or more voice processing components 124 (hereinafter “the voice components 124”) and several components described with respect to the playback device 110a (FIG. 1C) including the processors 112a, the memory 112b, and the microphones 115. The NMD 120a optionally comprises other components also included in the playback device 110a (FIG. 1C), such as the user interface 113 and/or the transducers 114. In some embodiments, the NMD 120a is configured as a media playback device (e.g., one or more of the playback devices 110), and further includes, for example, one or more of the audio components 112g (FIG. 1C), the amplifiers 112h, and/or other playback device components. In certain embodiments, the NMD 120a comprises an Internet of Things (IoT) device such as, for example, a thermostat, alarm panel, fire and/or smoke detector, etc. In some embodiments, the NMD 120a comprises the microphones 115, the voice processing components 124, and only a portion of the components of the electronics 112 described above with respect to FIG. 1C. In some aspects, for example, the NMD 120a includes the processor 112a and the memory 112b (FIG. 1C), while omitting one or more other components of the electronics 112. In some embodiments, the NMD 120a includes additional components (e.g., one or more sensors, cameras, thermometers, barometers, hygrometers, etc.).

In some embodiments, an NMD can be integrated into a playback device. FIG. 1G is a block diagram of a playback device 110r comprising an NMD 120d. The playback device 110r can comprise many or all of the components of the playback device 110a and further include the microphones 115 and voice processing components 124 (FIG. 1F). The playback device 110r optionally includes an integrated control device 130c. The control device 130c can comprise, for example, a user interface (e.g., the user interface 113 of FIG. 1C) configured to receive user input (e.g., touch input, voice input, etc.) without a separate control device. In other embodiments, however, the playback device 110r receives commands from another control device (e.g., the control device 130a of FIG. 1B). Additional NMD embodiments are described in further detail below with respect to FIGS. 3A-3F.

Referring again to FIG. 1F, the microphones 115 are configured to acquire, capture, and/or receive sound from an environment (e.g., the environment 101 of FIG. 1A) and/or a room in which the NMD 120a is positioned. The received sound can include, for example, vocal utterances, audio played back by the NMD 120a and/or another playback device, background voices, ambient sounds, etc. The microphones 115 convert the received sound into electrical signals to produce microphone data. The voice processing components 124 receive and analyze the microphone data to determine whether a voice input is present in the microphone data. The voice input can comprise, for example, an activation word followed by an utterance including a user request. As those of ordinary skill in the art will appreciate, an activation word is a word or other audio cue signifying a user voice input. For instance, in querying the AMAZON VAS, a user might speak the activation word “Alexa.” Other examples include “Ok, Google” for invoking the GOOGLE VAS and “Hey, Siri” for invoking the APPLE VAS.

After detecting the activation word, voice processing components 124 monitor the microphone data for an accompanying user request in the voice input. The user request may include, for example, a command to control a third-party device, such as a thermostat (e.g., NEST thermostat), an illumination device (e.g., a PHILIPS HUE lighting device), or a media playback device (e.g., a SONOS playback device). For example, a user might speak the activation word “Alexa” followed by the utterance “set the thermostat to 68 degrees” to set a temperature in a home (e.g., the environment 101 of FIG. 1A). The user might speak the same activation word followed by the utterance “turn on the living room” to turn on illumination devices in a living room area of the home. The user may similarly speak an activation word followed by a request to play a particular song, an album, or a playlist of music on a playback device in the home. Additional description regarding receiving and processing voice input data can be found in further detail below with respect to FIGS. 3A-3F.

d. Suitable Control Devices

FIG. 1H is a partial schematic diagram of the control device 130a (FIGS. 1A and 1B). As used herein, the term “control device” can be used interchangeably with “controller” or “control system.” Among other features, the control device 130a is configured to receive user input related to the media playback system 100 and, in response, cause one or more devices in the media playback system 100 to perform an action(s) or operation(s) corresponding to the user input. In the illustrated embodiment, the control device 130a comprises a smartphone (e.g., an iPhone™. an Android phone, etc.) on which media playback system controller application software is installed. In some embodiments, the control device 130a comprises, for example, a tablet (e.g., an iPad™), a computer (e.g., a laptop computer, a desktop computer, etc.), and/or another suitable device (e.g., a television, an automobile audio head unit, an IoT device, etc.). In certain embodiments, the control device 130a comprises a dedicated controller for the media playback system 100. In other embodiments, as described above with respect to FIG. 1G, the control device 130a is integrated into another device in the media playback system 100 (e.g., one more of the playback devices 110, NMDs 120, and/or other suitable devices configured to communicate over a network).

The control device 130a includes electronics 132, a user interface 133, one or more speakers 134, and one or more microphones 135. The electronics 132 comprise one or more processors 132a (referred to hereinafter as “the processors 132a”), a memory 132b, software components 132c, and a network interface 132d. The processor 132a can be configured to perform functions relevant to facilitating user access, control, and configuration of the media playback system 100. The memory 132b can comprise data storage that can be loaded with one or more of the software components executable by the processor 132a to perform those functions. The software components 132c can comprise applications and/or other executable software configured to facilitate control of the media playback system 100. The memory 132b can be configured to store, for example, the software components 132c, media playback system controller application software, and/or other data associated with the media playback system 100 and the user.

The network interface 132d is configured to facilitate network communications between the control device 130a and one or more other devices in the media playback system 100, and/or one or more remote devices. In some embodiments, the network interface 132d is configured to operate according to one or more suitable communication industry standards (e.g., infrared, radio, wired standards including IEEE 802.3, wireless standards including IEEE 802.11a, 802.11b, 802.11g, 802.11n, 802.11ac, 802.15, 4G, LTE, etc.). The network interface 132d can be configured, for example, to transmit data to and/or receive data from the playback devices 110, the NMDs 120, other ones of the control devices 130, one of the computing devices 106 of FIG. 1B, devices comprising one or more other media playback systems, etc. The transmitted and/or received data can include, for example, playback device control commands, state variables, playback zone and/or zone group configurations. For instance, based on user input received at the user interface 133, the network interface 132d can transmit a playback device control command (e.g., volume control, audio playback control, audio content selection, etc.) from the control device 130a to one or more of the playback devices 110. The network interface 132d can also transmit and/or receive configuration changes such as, for example, adding/removing one or more playback devices 110 to/from a zone, adding/removing one or more zones to/from a zone group, forming a bonded or consolidated player, separating one or more playback devices from a bonded or consolidated player, among others. Additional description of zones and groups can be found below with respect to FIGS. 1I through 1M.

The user interface 133 is configured to receive user input and can facilitate control of the media playback system 100. The user interface 133 includes media content art 133a (e.g., album art, lyrics, videos, etc.), a playback status indicator 133b (e.g., an elapsed and/or remaining time indicator), media content information region 133c, a playback control region 133d, and a zone indicator 133c. The media content information region 133c can include a display of relevant information (e.g., title, artist, album, genre, release year, etc.) about media content currently playing and/or media content in a queue or playlist. The playback control region 133d can include selectable (e.g., via touch input and/or via a cursor or another suitable selector) icons to cause one or more playback devices in a selected playback zone or zone group to perform playback actions such as, for example, play or pause, fast forward, rewind, skip to next, skip to previous, enter/exit shuffle mode, enter/exit repeat mode, enter/exit cross fade mode, etc. The playback control region 133d may also include selectable icons to modify equalization settings, playback volume, and/or other suitable playback actions. In the illustrated embodiment, the user interface 133 comprises a display presented on a touch screen interface of a smartphone (e.g., an iPhone™ an Android phone, etc.). In some embodiments, however, user interfaces of varying formats, styles, and interactive sequences may alternatively be implemented on one or more network devices to provide comparable control access to a media playback system.

The one or more speakers 134 (e.g., one or more transducers) can be configured to output sound to the user of the control device 130a. In some embodiments, the one or more speakers comprise individual transducers configured to correspondingly output low frequencies, mid-range frequencies, and/or high frequencies. In some aspects, for example, the control device 130a is configured as a playback device (e.g., one of the playback devices 110). Similarly, in some embodiments the control device 130a is configured as an NMD (e.g., one of the NMDs 120), receiving voice commands and other sounds via the one or more microphones 135.

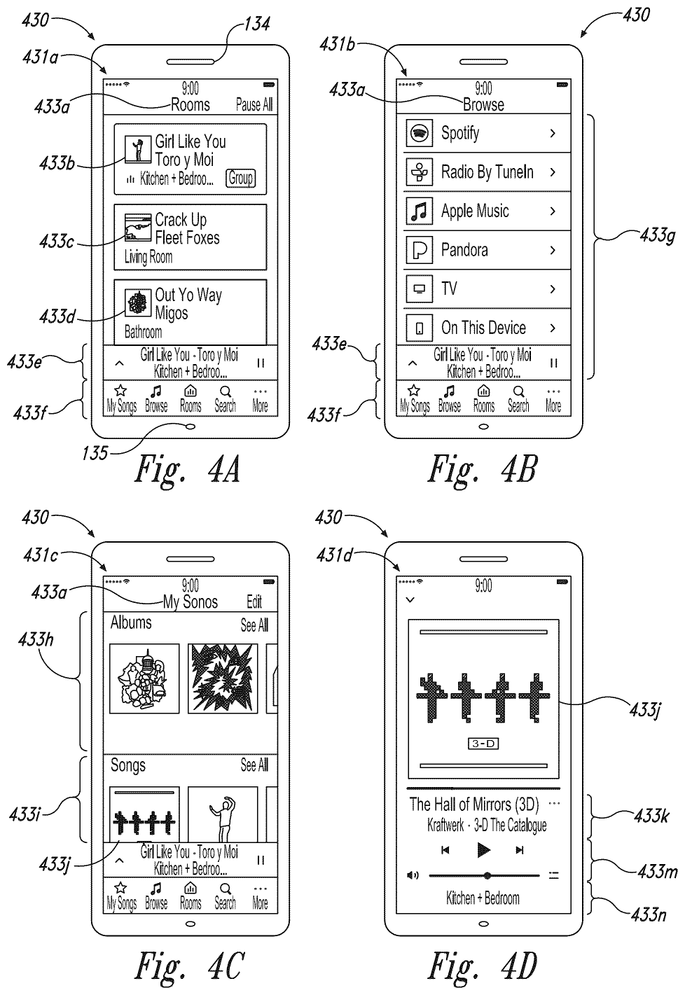

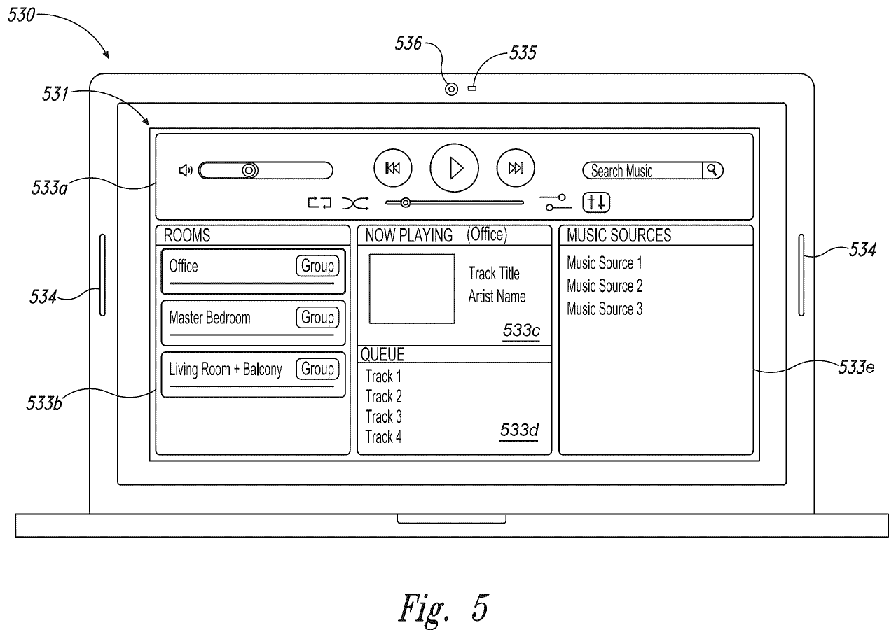

The one or more microphones 135 can comprise, for example, one or more condenser microphones, electret condenser microphones, dynamic microphones, and/or other suitable types of microphones or transducers. In some embodiments, two or more of the microphones 135 are arranged to capture location information of an audio source (e.g., voice, audible sound, etc.) and/or configured to facilitate filtering of background noise. Moreover, in certain embodiments, the control device 130a is configured to operate as a playback device and an NMD. In other embodiments, however, the control device 130a omits the one or more speakers 134 and/or the one or more microphones 135. For instance, the control device 130a may comprise a device (e.g., a thermostat, an IoT device, a network device, etc.) comprising a portion of the electronics 132 and the user interface 133 (e.g., a touch screen) without any speakers or microphones. Additional control device embodiments are described in further detail below with respect to FIGS. 4A-4D and 5.

c. Suitable Playback Device Configurations

FIGS. 1I through 1M show example configurations of playback devices in zones and zone groups. Referring first to FIG. 1M, in one example, a single playback device may belong to a zone. For example, the playback device 110g in the second bedroom 101c (FIG. 1A) may belong to Zone C. In some implementations described below, multiple playback devices may be “bonded” to form a “bonded pair” which together form a single zone. For example, the playback device 110l (e.g., a left playback device) can be bonded to the playback device 110m (e.g., a right playback device) to form Zone B. Bonded playback devices may have different playback responsibilities (e.g., channel responsibilities). In another implementation described below, multiple playback devices may be merged to form a single zone. For example, the playback device 110h (e.g., a front playback device) may be merged with the playback device 110i (e.g., a subwoofer), and the playback devices 110j and 110k (e.g., left and right surround speakers, respectively) to form a single Zone D. In another example, the playback devices 110b and 110d can be merged to form a merged group or a zone group 108b. The merged playback devices 110b and 110d may not be specifically assigned different playback responsibilities. That is, the merged playback devices 110b and 110d may, aside from playing audio content in synchrony, each play audio content as they would if they were not merged.

Each zone in the media playback system 100 may be provided for control as a single user interface (UI) entity. For example, Zone A may be provided as a single entity named Master Bathroom. Zone B may be provided as a single entity named Master Bedroom. Zone C may be provided as a single entity named Second Bedroom.

Playback devices that are bonded may have different playback responsibilities, such as responsibilities for certain audio channels. For example, as shown in FIG. 1I, the playback devices 110l and 110m may be bonded so as to produce or enhance a stereo effect of audio content. In this example, the playback device 110l may be configured to play a left channel audio component, while the playback device 110m may be configured to play a right channel audio component. In some implementations, such stereo bonding may be referred to as “pairing.”

Additionally, bonded playback devices may have additional and/or different respective speaker drivers. As shown in FIG. 1J, the playback device 110h named Front may be bonded with the playback device 110i named SUB. The Front device 110h can be configured to render a range of mid to high frequencies and the SUB device 110i can be configured to render low frequencies. When unbonded, however, the Front device 110h can be configured to render a full range of frequencies. As another example, FIG. 1K shows the Front and SUB devices 110h and 110i further bonded with Left and Right playback devices 110j and 110k, respectively. In some implementations, the Left and Right devices 110j and 110k can be configured to form surround or “satellite” channels of a home theater system. The bonded playback devices 110h, 110i, 110j, and 110k may form a single Zone D (FIG. 1M).

Playback devices that are merged may not have assigned playback responsibilities, and may each render the full range of audio content the respective playback device is capable of. Nevertheless, merged devices may be represented as a single UI entity (i.e., a zone, as discussed above). For instance, the playback devices 110a and 110n in the master bathroom have the single UI entity of Zone A. In one embodiment, the playback devices 110a and 110n may each output the full range of audio content each respective playback devices 110a and 110n are capable of, in synchrony.

In some embodiments, an NMD is bonded or merged with another device so as to form a zone. For example, the NMD 120b may be bonded with the playback device 110e, which together form Zone F, named Living Room. In other embodiments, a stand-alone network microphone device may be in a zone by itself. In other embodiments, however, a stand-alone network microphone device may not be associated with a zone. Additional details regarding associating network microphone devices and playback devices as designated or default devices may be found, for example, in subsequently referenced U.S. Pat. No. 10,499,146.

Zones of individual, bonded, and/or merged devices may be grouped to form a zone group. For example, referring to FIG. 1M, Zone A may be grouped with Zone B to form a zone group 108a that includes the two zones. Similarly, Zone G may be grouped with Zone H to form the zone group 108b. As another example, Zone A may be grouped with one or more other Zones C-I. The Zones A-I may be grouped and ungrouped in numerous ways. For example, three, four, five, or more (e.g., all) of the Zones A-I may be grouped. When grouped, the zones of individual and/or bonded playback devices may play back audio in synchrony with one another, as described in previously referenced U.S. Pat. No. 8,234,395. Playback devices may be dynamically grouped and ungrouped to form new or different groups that synchronously play back audio content.

In various implementations, the zones in an environment may be the default name of a zone within the group or a combination of the names of the zones within a zone group. For example, Zone Group 108b can be assigned a name such as “Dining+Kitchen”, as shown in FIG. 1M. In some embodiments, a zone group may be given a unique name selected by a user.

Certain data may be stored in a memory of a playback device (e.g., the memory 112b of FIG. 1C) as one or more state variables that are periodically updated and used to describe the state of a playback zone, the playback device(s), and/or a zone group associated therewith. The memory may also include the data associated with the state of the other devices of the media system, and shared from time to time among the devices so that one or more of the devices have the most recent data associated with the system.

In some embodiments, the memory may store instances of various variable types associated with the states. Variable instances may be stored with identifiers (e.g., tags) corresponding to type. For example, certain identifiers may be a first type “a1” to identify playback device(s) of a zone, a second type “b1” to identify playback device(s) that may be bonded in the zone, and a third type “c1” to identify a zone group to which the zone may belong. As a related example, identifiers associated with the second bedroom 101c may indicate that the playback device is the only playback device of the Zone C and not in a zone group. Identifiers associated with the Den may indicate that the Den is not grouped with other zones but includes bonded playback devices 110h-110k. Identifiers associated with the Dining Room may indicate that the Dining Room is part of the Dining+Kitchen zone group 108b and that devices 110b and 110d are grouped (FIG. 1L). Identifiers associated with the Kitchen may indicate the same or similar information by virtue of the Kitchen being part of the Dining+Kitchen zone group 108b. Other example zone variables and identifiers are described below.

In yet another example, the memory may store variables or identifiers representing other associations of zones and zone groups, such as identifiers associated with Areas, as shown in FIG. 1M. An area may involve a cluster of zone groups and/or zones not within a zone group. For instance, FIG. 1M shows an Upper Area 109a including Zones A-D and I, and a Lower Area 109b including Zones E-I. In one aspect, an Area may be used to invoke a cluster of zone groups and/or zones that share one or more zones and/or zone groups of another cluster. In another aspect, this differs from a zone group, which does not share a zone with another zone group. Further examples of techniques for implementing Areas may be found, for example, in U.S. Pat. No. 10,712,997 filed Aug. 21, 2017, and titled “Room Association Based on Name,” and U.S. Pat. No. 8,483,853 filed Sep. 11, 2007, and titled “Controlling and manipulating groupings in a multi-zone media system.” Each of these patents is incorporated herein by reference in its entirety. In some embodiments, the media playback system 100 may not implement Areas, in which case the system may not store variables associated with Areas.

### III. Example Systems and Devices

FIG. 2A is a front isometric view of a playback device 210 configured in accordance with aspects of the disclosed technology. FIG. 2B is a front isometric view of the playback device 210 without a grille 216e. FIG. 2C is an exploded view of the playback device 210. Referring to FIGS. 2A-2C together, the playback device 210 comprises a housing 216 that includes an upper portion 216a, a right or first side portion 216b, a lower portion, a left or second side portion 216d, the grille 216e, and a rear portion 216f. A plurality of fasteners 216g (e.g., one or more screws, rivets, clips) attaches a frame 216h to the housing 216. A cavity 216j (FIG. 2C) in the housing 216 is configured to receive the frame 216h and electronics 212. The frame 216h is configured to carry a plurality of transducers 214 (identified individually in FIG. 2B as transducers 214a-f). The electronics 212 (e.g., the electronics 112 of FIG. 1C) are configured to receive audio content from an audio source and send electrical signals corresponding to the audio content to the transducers 214 for playback.

The transducers 214 are configured to receive the electrical signals from the electronics 112, and further configured to convert the received electrical signals into audible sound during playback. For instance, the transducers 214a-c (e.g., tweeters) can be configured to output high frequency sound (e.g., sound waves having a frequency greater than about 2 kHz). The transducers 214d-f (e.g., mid-woofers, woofers, midrange speakers) can be configured output sound at frequencies lower than the transducers 214a-c (e.g., sound waves having a frequency lower than about 2 kHz). In some embodiments, the playback device 210 includes a number of transducers different than those illustrated in FIGS. 2A-2C. For example, as described in further detail below with respect to FIGS. 3A-3C, the playback device 210 can include fewer than six transducers (e.g., one, two, three). In other embodiments, however, the playback device 210 includes more than six transducers (e.g., nine, ten). Moreover, in some embodiments, all or a portion of the transducers 214 are configured to operate as a phased array to desirably adjust (e.g., narrow or widen) a radiation pattern of the transducers 214, thereby altering a user's perception of the sound emitted from the playback device 210.

In some examples, a filter is axially aligned with the transducer 214b. The filter can be configured to desirably attenuate a predetermined range of frequencies that the transducer 214b outputs to improve sound quality and a perceived sound stage output collectively by the transducers 214. In some embodiments, however, the playback device 210 omits the filter. In other embodiments, the playback device 210 includes one or more additional filters aligned with the transducers 214b and/or at least another of the transducers 214.

FIGS. 3A and 3B are front and right isometric side views, respectively, of an NMD 320 configured in accordance with embodiments of the disclosed technology. FIG. 3C is an exploded view of the NMD 320. FIG. 3D is an enlarged view of a portion of FIG. 3B including a user interface 313 of the NMD 320. Referring first to FIGS. 3A-3C, the NMD 320 includes a housing 316 comprising an upper portion 316a, a lower portion 316b and an intermediate portion 316c (e.g., a grille). A plurality of ports, holes or apertures 316d in the upper portion 316a allow sound to pass through to one or more microphones 315 (FIG. 3C) positioned within the housing 316. The one or more microphones 315 are configured to receive sound via the apertures 316d and produce electrical signals based on the received sound. In the illustrated embodiment, a frame 316e (FIG. 3C) of the housing 316 surrounds cavities 316f and 316g configured to house, respectively, a first transducer 314a (e.g., a tweeter) and a second transducer 314b (e.g., a mid-woofer, a midrange speaker, a woofer). In other embodiments, however, the NMD 320 includes a single transducer, or more than two (e.g., two, five, six) transducers. In certain embodiments, the NMD 320 omits the transducers 314a and 314b altogether.

Electronics 312 (FIG. 3C) includes components configured to drive the transducers 314a and 314b, and further configured to analyze audio data corresponding to the electrical signals produced by the one or more microphones 315. In some embodiments, for example, the electronics 312 comprises many or all of the components of the electronics 112 described above with respect to FIG. 1C. In certain embodiments, the electronics 312 includes components described above with respect to FIG. 1F such as, for example, the one or more processors 112a, the memory 112b, the software components 112c, the network interface 112d, etc. In some embodiments, the electronics 312 includes additional suitable components (e.g., proximity or other sensors).

Referring to FIG. 3D, the user interface 313 includes a plurality of control surfaces (e.g., buttons, knobs, capacitive surfaces) including a first control surface 313a (e.g., a previous control), a second control surface 313b (e.g., a next control), and a third control surface 313c (e.g., a play and/or pause control) that can be adjusted by a user 323. A fourth control surface 313d is configured to receive touch input corresponding to activation and deactivation of the one or microphones 315. A first indicator 313e (e.g., one or more light emitting diodes (LEDs) or another suitable illuminator) can be configured to illuminate only when the one or more microphones 315 are activated. A second indicator 313f (e.g., one or more LEDs) can be configured to remain solid during normal operation and to blink or otherwise change from solid to indicate a detection of voice activity. In some embodiments, the user interface 313 includes additional or fewer control surfaces and illuminators. In one embodiment, for example, the user interface 313 includes the first indicator 313e, omitting the second indicator 313f. Moreover, in certain embodiments, the NMD 320 comprises a playback device and a control device, and the user interface 313 comprises the user interface of the control device.

Referring to FIGS. 3A-3D together, the NMD 320 is configured to receive voice commands from one or more adjacent users via the one or more microphones 315. As described above with respect to FIG. 1B, the one or more microphones 315 can acquire, capture, or record sound in a vicinity (e.g., a region within 10 m or less of the NMD 320) and transmit electrical signals corresponding to the recorded sound to the electronics 312. The electronics 312 can process the electrical signals and can analyze the resulting audio data to determine a presence of one or more voice commands (e.g., one or more activation words). In some embodiments, for example, after detection of one or more suitable voice commands, the NMD 320 is configured to transmit a portion of the recorded audio data to another device and/or a remote server (e.g., one or more of the computing devices 106 of FIG. 1B) for further analysis. The remote server can analyze the audio data, determine an appropriate action based on the voice command, and transmit a message to the NMD 320 to perform the appropriate action. For instance, a user may speak “Sonos, play Michael Jackson.” The NMD 320 can, via the one or more microphones 315, record the user's voice utterance, determine the presence of a voice command, and transmit the audio data having the voice command to a remote server (e.g., one or more of the remote computing devices 106 of FIG. 1B, one or more servers of a VAS and/or another suitable service). The remote server can analyze the audio data and determine an action corresponding to the command. The remote server can then transmit a command to the NMD 320 to perform the determined action (e.g., play back audio content related to Michael Jackson). The NMD 320 can receive the command and play back the audio content related to Michael Jackson from a media content source. As described above with respect to FIG. 1B, suitable content sources can include a device or storage communicatively coupled to the NMD 320 via a LAN (e.g., the network 104 of FIG. 1B), a remote server (e.g., one or more of the remote computing devices 106 of FIG. 1B), etc. In certain embodiments, however, the NMD 320 determines and/or performs one or more actions corresponding to the one or more voice commands without intervention or involvement of an external device, computer, or server.

FIG. 3E is a functional block diagram showing additional features of the NMD 320 in accordance with aspects of the disclosure. The NMD 320 includes components configured to facilitate voice command capture including voice activity detector component(s) 312k, beam former components 312l, acoustic echo cancellation (AEC) and/or self-sound suppression components 312m, activation word detector components 312n, and voice/speech conversion components 3120 (e.g., voice-to-text and text-to-voice). In the illustrated embodiment of FIG. 3E, the foregoing components 312k-3120 are shown as separate components. In some embodiments, however, one or more of the components 312k-3120 are subcomponents of the processors 112a.

The beamforming and self-sound suppression components 312l and 312m are configured to detect an audio signal and determine aspects of voice input represented in the detected audio signal, such as the direction, amplitude, frequency spectrum, etc. The voice activity detector activity components 312k are operably coupled with the beamforming and AEC components 312l and 312m and are configured to determine a direction and/or directions from which voice activity is likely to have occurred in the detected audio signal. Potential speech directions can be identified by monitoring metrics which distinguish speech from other sounds. Such metrics can include, for example, energy within the speech band relative to background noise and entropy within the speech band, which is measure of spectral structure. As those of ordinary skill in the art will appreciate, speech typically has a lower entropy than most common background noise. The activation word detector components 312n are configured to monitor and analyze received audio to determine if any activation words (e.g., wake words) are present in the received audio. The activation word detector components 312n may analyze the received audio using an activation word detection algorithm. If the activation word detector 312n detects an activation word, the NMD 320 may process voice input contained in the received audio. Example activation word detection algorithms accept audio as input and provide an indication of whether an activation word is present in the audio. Many first- and third-party activation word detection algorithms are known and commercially available. For instance, operators of a voice service may make their algorithm available for use in third-party devices. Alternatively, an algorithm may be trained to detect certain activation words. In some embodiments, the activation word detector 312n runs multiple activation word detection algorithms on the received audio simultaneously (or substantially simultaneously). As noted above, different voice services (e.g., AMAZON's ALEXA, APPLE's SIRI, or MICROSOFT's CORTANA) can each use a different activation word for invoking their respective voice service. To support multiple services, the activation word detector 312n may run the received audio through the activation word detection algorithm for each supported voice service in parallel.

The speech/text conversion components 3120 may facilitate processing by converting speech in the voice input to text. In some embodiments, the electronics 312 can include voice recognition software that is trained to a particular user or a particular set of users associated with a household. Such voice recognition software may implement voice-processing algorithms that are tuned to specific voice profile(s). Tuning to specific voice profiles may require less computationally intensive algorithms than traditional voice activity services, which typically sample from a broad base of users and diverse requests that are not targeted to media playback systems.

FIG. 3F is a schematic diagram of an example voice input 328 captured by the NMD 320 in accordance with aspects of the disclosure. The voice input 328 can include an activation word portion 328a and a voice utterance portion 328b. In some embodiments, the activation word 328a can be a known activation word, such as “Alexa,” which is associated with AMAZON's ALEXA. In other embodiments, however, the voice input 328 may not include an activation word. In some embodiments, a network microphone device may output an audible and/or visible response upon detection of the activation word portion 328a. In addition, or alternately, an NMD may output an audible and/or visible response after processing a voice input and/or a series of voice inputs.

The voice utterance portion 328b may include, for example, one or more spoken commands (identified individually as a first command 328c and a second command 328c) and one or more spoken keywords (identified individually as a first keyword 328d and a second keyword 328f). In one example, the first command 328c can be a command to play music, such as a specific song, album, playlist, etc. In this example, the keywords may be one or words identifying one or more zones in which the music is to be played, such as the Living Room and the Dining Room shown in FIG. 1A. In some examples, the voice utterance portion 328b can include other information, such as detected pauses (e.g., periods of non-speech) between words spoken by a user, as shown in FIG. 3F. The pauses may demarcate the locations of separate commands, keywords, or other information spoke by the user within the voice utterance portion 328b.

In some embodiments, the media playback system 100 is configured to temporarily reduce the volume of audio content that it is playing while detecting the activation word portion 328a. The media playback system 100 may restore the volume after processing the voice input 328, as shown in FIG. 3F. Such a process can be referred to as ducking, examples of which are disclosed in U.S. Pat. No. 10,499,146, which is incorporated by reference herein in its entirety.

FIGS. 4A-4D are schematic diagrams of a control device 430 (e.g., the control device 130a of FIG. 1H, a smartphone, a tablet, a dedicated control device, an IoT device, and/or another suitable device) showing corresponding user interface displays in various states of operation. A first user interface display 431a (FIG. 4A) includes a display name 433a (i.e., “Rooms”). A selected group region 433b displays audio content information (e.g., artist name, track name, album art) of audio content played back in the selected group and/or zone. Group regions 433c and 433d display corresponding group and/or zone name, and audio content information audio content played back or next in a playback queue of the respective group or zone. An audio content region 433e includes information related to audio content in the selected group and/or zone (i.e., the group and/or zone indicated in the selected group region 433b). A lower display region 433f is configured to receive touch input to display one or more other user interface displays. For example, if a user selects “Browse” in the lower display region 433f, the control device 430 can be configured to output a second user interface display 431b (FIG. 4B) comprising a plurality of music services 433g (e.g., Spotify, Radio by Tunein, Apple Music, Pandora, Amazon, TV, local music, line-in) through which the user can browse and from which the user can select media content for play back via one or more playback devices (e.g., one of the playback devices 110 of FIG. 1A). Alternatively, if the user selects “My Sonos” in the lower display region 433f, the control device 430 can be configured to output a third user interface display 431c (FIG. 4C). A first media content region 433h can include graphical representations (e.g., album art) corresponding to individual albums, stations, or playlists. A second media content region 433i can include graphical representations (e.g., album art) corresponding to individual songs, tracks, or other media content. If the user selects a graphical representation 433j (FIG. 4C), the control device 430 can be configured to begin play back of audio content corresponding to the graphical representation 433j and output a fourth user interface display 431d that includes an enlarged version of the graphical representation 433j, media content information 433k (e.g., track name, artist, album), transport controls 433m (e.g., play, previous, next, pause, volume), and indication 433n of the currently selected group and/or zone name.

FIG. 5 is a schematic diagram of a control device 530 (e.g., a laptop computer, a desktop computer). The control device 530 includes transducers 534, a microphone 535, and a camera 536. A user interface 531 includes a transport control region 533a, a playback status region 533c, a playback zone region 533b, a playback queue region 533d, and a media content source region 533e. The transport control region comprises one or more controls for controlling media playback including, for example, volume, previous, play/pause, next, repeat, shuffle, track position, crossfade, equalization, etc. The audio content source region 533e includes a listing of one or more media content sources from which a user can select media items for play back and/or adding to a playback queue.

The playback zone region 533b can include representations of playback zones within the media playback system 100 (FIGS. 1A and 1B). In some embodiments, the graphical representations of playback zones may be selectable to bring up additional selectable icons to manage or configure the playback zones in the media playback system, such as a creation of bonded zones, creation of zone groups, separation of zone groups, renaming of zone groups, etc. In the illustrated embodiment, a “group” icon is provided within each of the graphical representations of playback zones. The “group” icon provided within a graphical representation of a particular zone may be selectable to bring up options to select one or more other zones in the media playback system to be grouped with the particular zone. Once grouped, playback devices in the zones that have been grouped with the particular zone can be configured to play audio content in synchrony with the playback device(s) in the particular zone. Analogously, a “group” icon may be provided within a graphical representation of a zone group. In the illustrated embodiment, the “group” icon may be selectable to bring up options to deselect one or more zones in the zone group to be removed from the zone group. In some embodiments, the control device 530 includes other interactions and implementations for grouping and ungrouping zones via the user interface 531. In certain embodiments, the representations of playback zones in the playback zone region 533b can be dynamically updated as playback zone or zone group configurations are modified.

The playback status region 533c includes graphical representations of audio content that is presently being played, previously played, or scheduled to play next in the selected playback zone or zone group. The selected playback zone or zone group may be visually distinguished on the user interface, such as within the playback zone region 533b and/or the playback queue region 533d. The graphical representations may include track title, artist name, album name, album year, track length, and other relevant information that may be useful for the user to know when controlling the media playback system 100 via the user interface 531.

The playback queue region 533d includes graphical representations of audio content in a playback queue associated with the selected playback zone or zone group. In some embodiments, each playback zone or zone group may be associated with a playback queue containing information corresponding to zero or more audio items for playback by the playback zone or zone group. For instance, each audio item in the playback queue may comprise a uniform resource identifier (URI), a uniform resource locator (URL) or some other identifier that may be used by a playback device in the playback zone or zone group to find and/or retrieve the audio item from a local audio content source or a networked audio content source, possibly for playback by the playback device. In some embodiments, for example, a playlist can be added to a playback queue, in which information corresponding to each audio item in the playlist may be added to the playback queue. In some embodiments, audio items in a playback queue may be saved as a playlist. In certain embodiments, a playback queue may be empty, or populated but “not in use” when the playback zone or zone group is playing continuously streaming audio content, such as Internet radio that may continue to play until otherwise stopped, rather than discrete audio items that have playback durations. In some embodiments, a playback queue can include Internet radio and/or other streaming audio content items and be “in use” when the playback zone or zone group is playing those items.

When playback zones or zone groups are “grouped” or “ungrouped,” playback queues associated with the affected playback zones or zone groups may be cleared or re-associated. For example, if a first playback zone including a first playback queue is grouped with a second playback zone including a second playback queue, the established zone group may have an associated playback queue that is initially empty, that contains audio items from the first playback queue (such as if the second playback zone was added to the first playback zone), that contains audio items from the second playback queue (such as if the first playback zone was added to the second playback zone), or a combination of audio items from both the first and second playback queues. Subsequently, if the established zone group is ungrouped, the resulting first playback zone may be re-associated with the previous first playback queue, or be associated with a new playback queue that is empty or contains audio items from the playback queue associated with the established zone group before the established zone group was ungrouped. Similarly, the resulting second playback zone may be re-associated with the previous second playback queue, or be associated with a new playback queue that is empty, or contains audio items from the playback queue associated with the established zone group before the established zone group was ungrouped.

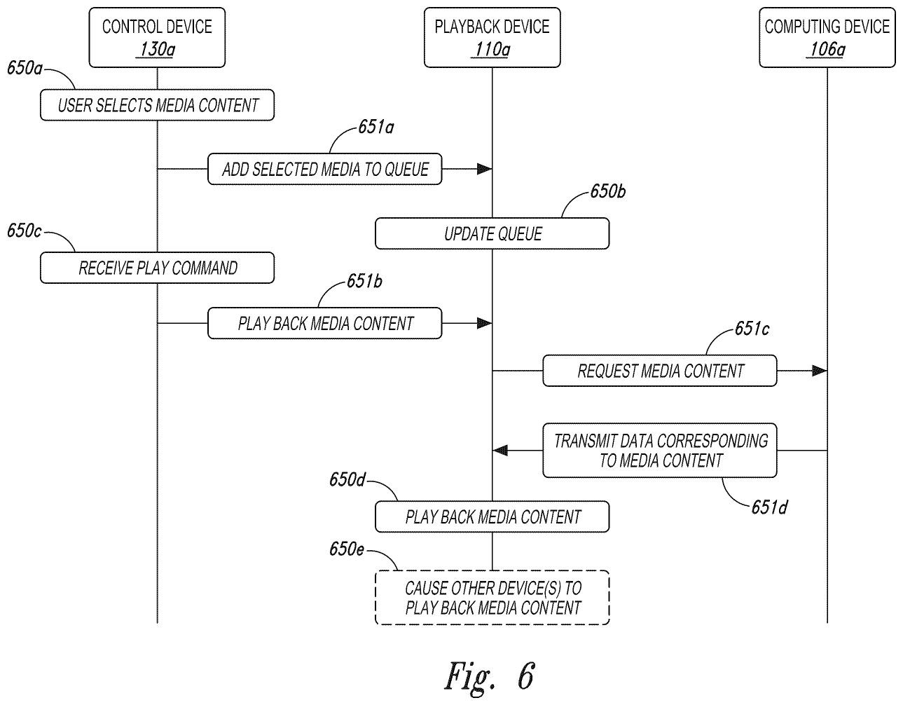

FIG. 6 is a message flow diagram illustrating data exchanges between devices of the media playback system 100 (FIGS. 1A-1M).

At step 650a, the media playback system 100 receives an indication of selected media content (e.g., one or more songs, albums, playlists, podcasts, videos, stations) via the control device 130a. The selected media content can comprise, for example, media items stored locally on one or more devices (e.g., the audio source 105 of FIG. 1C) connected to the media playback system and/or media items stored on one or more media service servers (one or more of the remote computing devices 106 of FIG. 1B). In response to receiving the indication of the selected media content, the control device 130a transmits a message 651a to the playback device 110a (FIGS. 1A-1C) to add the selected media content to a playback queue on the playback device 110a.

At step 650b, the playback device 110a receives the message 651a and adds the selected media content to the playback queue for play back.

At step 650c, the control device 130a receives input corresponding to a command to play back the selected media content. In response to receiving the input corresponding to the command to play back the selected media content, the control device 130a transmits a message 651b to the playback device 110a causing the playback device 110a to play back the selected media content. In response to receiving the message 651b, the playback device 110a transmits a message 651c to the computing device 106a requesting the selected media content. The computing device 106a, in response to receiving the message 651c, transmits a message 651d comprising data (e.g., audio data, video data, a URL, a URI) corresponding to the requested media content.

At step 650d, the playback device 110a receives the message 651d with the data corresponding to the requested media content and plays back the associated media content.

At step 650e, the playback device 110a optionally causes one or more other devices to play back the selected media content. In one example, the playback device 110a is one of a bonded zone of two or more players (FIG. 1M). The playback device 110a can receive the selected media content and transmit all or a portion of the media content to other devices in the bonded zone. In another example, the playback device 110a is a coordinator of a group and is configured to transmit and receive timing information from one or more other devices in the group. The other one or more devices in the group can receive the selected media content from the computing device 106a, and begin playback of the selected media content in response to a message from the playback device 110a such that all of the devices in the group play back the selected media content in synchrony.

### IV. Example Systems, Devices, and Methods of Dynamic Equalization for Power Management

According to various embodiments, playback devices such as those described above can be configured to receive both audio data and line power via a powered communication port, such as a PoE port, for example. Different implementations of powered communication ports may support different power levels and/or variants of the PoE standard. As described herein, the playback device generally includes one or more amplifiers configured to drive one or more speakers to provide an audio output. In such examples where the playback device is configured to receive power over a combined power/communication line, power supply circuitry can be used to provide conditioned power for supplying the one or more amplifiers with input power to output undistorted audio via an output device such as the one or more speakers.

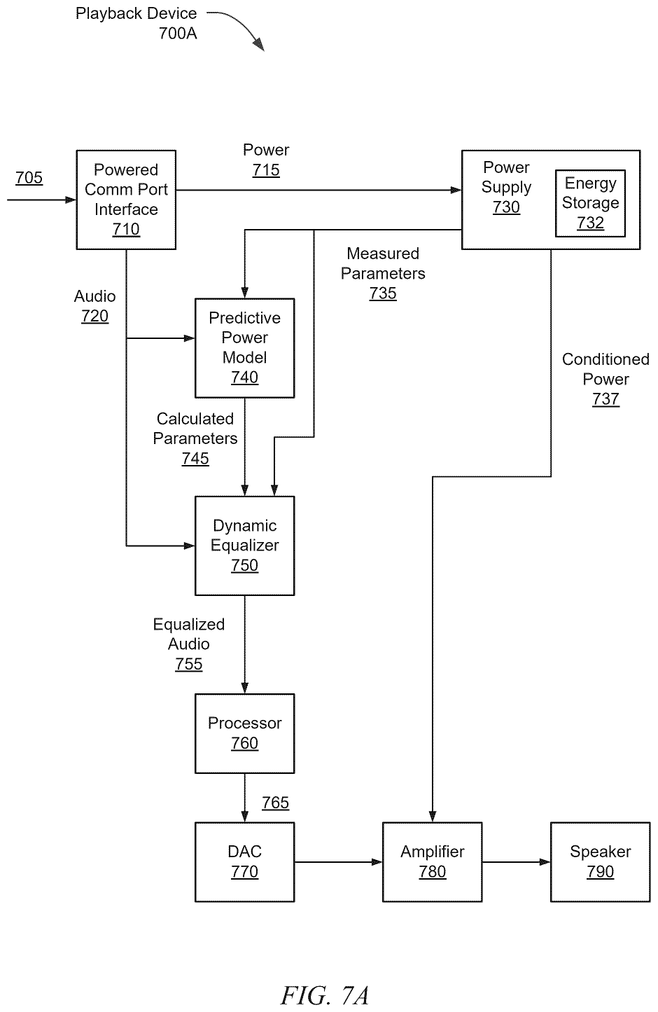

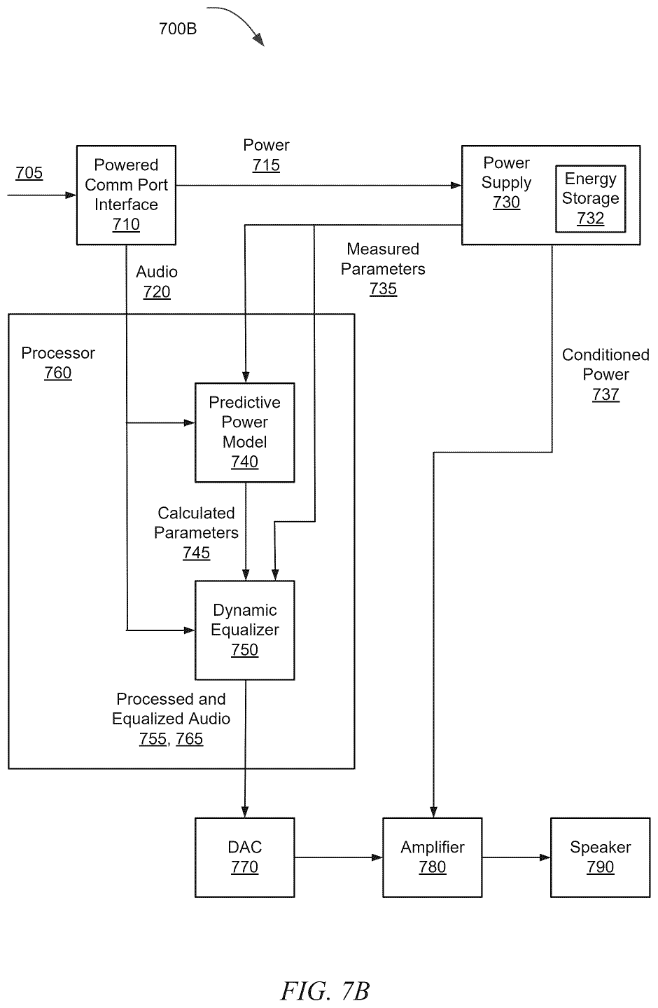

FIG. 7A is a block diagram of an example playback device 700A configured in accordance with aspects of the disclosed technology. The playback device is shown to include a powered communication port interface 710, a power supply circuitry 730, a predictive power model 740, a dynamic equalizer 750, a processor 760, a DAC 770, an amplifier 780, and a speaker 790. In some embodiments, the DAC 770 and amplifier 780 may be combined, for example in a single amplifier integrated circuit (IC).

In some embodiments, the powered communication port interface 710 is configured to receive both audio data 720 and line power 715 via a single cable such as an Ethernet or USB cable 705. The line power that can be provided by the port interface 710 is limited to a maximum power and a maximum current. The maximum power and a maximum current are theoretical values, and the actual maximum power and maximum current are generally lower and depend on a number of factors including cable length and impedance.

In some embodiments, the power supply circuitry 730 is configured to condition the line power 715 received through the powered communication port interface 710, to provide conditioned power 737 to the amplifier 780 to drive the speaker 790. The amplifier 780 may have a peak power consumption that is greater than the maximum power of the line power 715, for example at times when the audio 720 contains higher energy segments such as representations of the hit of a snare drum or a bass-heavy section of music.

The power supply circuitry 730 may include one or more energy storage elements 732 which can be charged to store energy and supply the conditioned power 737 at least in part by discharging a portion of the energy stored in the element. In some embodiments, the energy storage elements may include capacitors, batteries, or other suitable components. Energy storage elements will be referred to as capacitors herein for convenience. The discharged energy from the capacitor may limit the current draw of the power supply circuitry to a level that is less than the maximum current of the line power 715, to the extent possible based on the amount of stored charge in the capacitors.

Further examples of techniques for employing capacitors to store energy may be found, for example, in PCT Application No. PCT/US2023/074473 filed Sep. 18, 2023, and titled “Space Efficient Power Over Ethernet for Audio Playback Devices,” which is incorporated herein by reference in its entirety.

In some cases, however, the reserve energy stored in the capacitors may be insufficient to prevent the current draw from exceeding the maximum current of the line power. For instance, certain audio tracks may have bass-heavy sections that repeatedly demand power from the capacitors without providing a sufficient amount of time for the capacitors to be recharged. If the voltage across the capacitor drops too low, distortion may be introduced (e.g., in the form of audio clipping) and/or the playback device may reboot (e.g., if the voltage and/or current levels to the digital circuitry of the playback device fall too low).

To handle these instances, the dynamic equalizer 750 is configured to generate equalized audio 755 to reduce the energy required to render the audio signal 720 as needed, to mitigate distortion and other problems resulting from insufficient power. In some embodiments, attenuation may be applied within a narrow spectral region that is associated with greater power consumption, for example bass frequencies. This form of attenuation may substantially reduce the energy required to render the audio signal 720 (e.g., particularly at higher volume levels) while being less perceptible to the user. In some instances, the dynamic equalizer can leverage information provided by the predictive power model 740, to determine when and how much attenuation should be applied to reduce the power draw. Additionally (or alternatively), attenuation may be applied to a broad spectral region during brief periods of high-power consumption (e.g., hits of a bass drum) to avoid fully depleting the energy storage element(s) 732 (e.g., avoiding a situation where the playback device crashes and/or reboots).

In some embodiments, the predictive power model(s) 740 is configured to model the actual power being provided by the powered communication port interface 710 and to predict the power that will be needed to play an upcoming portion of the audio signal 720. Additionally (or alternative), the predictive power model(s) 740 may predict a future state of one or more components of the power supply circuitry 730, such as a state of the energy storage element 732 (e.g., a voltage across one or more capacitors, a state-of-charge of a battery, etc.). The predictive power model(s) 740 may be employed to generate calculated parameter(s) 745 that may be used as inputs for the dynamic equalizer 750 based on the, for example, the audio 720 and one or more measured parameter(s) 735 from the power supply circuitry 730. Examples of calculated parameter(s) include, for example, an indication of power availability (e.g., a power budget), an indication of a future state of the energy storage elements 732, etc.

It should be appreciated that the predictive power model(s) 740 may be constructed in any of a variety of ways. For instance, the predictive power model(s) 740 may be constructed using one or more power consumption characteristics of the playback device 700A that are characterized at time of design. For example, the impedance of one or more audio transducers (e.g., a woofer, a tweeter, etc.) may be characterized along with the power consumption curves of one or more audio amplifiers 780 to construct a model that estimates the power required to reproduce a given audio signal (e.g., the power required for the amplifiers to drive the audio transducers in accordance with an input audio signal). Additionally (or alternatively), the power consumption of components other than the audio amplifier and the audio transducers may also be included to generate a more accurate wholistic power estimate. For instance, the power consumption of processor circuitry and/or wireless radio circuitry may be modeled as a constant power draw given that the power consumption of such components tends to be less impacted by the specific audio that is being played back.

In some embodiments, the predictive power model 740 may use information from a number of sources including, but not limited to, the measured parameters 735 of the power supply (e.g., voltages, currents, and/or power levels associated with the power supply), the predicted voltage of the power supply capacitor, the predicted energy requirements of the segment of the audio signal being played, and known electroacoustic characteristics of the amplifier 780 and speaker 790.

In some embodiments, the predictive power model 740 provides a threshold value 745 to the dynamic equalizer 750 for use in determining when and how much attenuation should be applied to reduce the power draw, as will be explained below. In some examples, the threshold value may represent a threshold for the measured parameters 735 such that when the measured capacitor voltage falls below the threshold voltage, the dynamic equalizer is called upon to reduce the required power. In some examples, the threshold voltage may be based on known characteristics of the capacitors and on a power budget that is calculated to include the specified power delivering capability of the interface 710 (e.g., whether PoE or PoE+).

In some embodiments, the playback device may include at least one processor 760 and at least one non-transitory computer-readable medium (not shown) comprising program instructions that are executable by the at least one processor such that the playback device is configured to drive the one or more amplifiers 780 to play back at least a portion of the equalized audio data 755. In some embodiments, the at least one processor 760 may include the one or more processors 112a described previously and may be configured to perform any desired audio processing functions such as mixing, format conversions, rate conversions, etc., to generate processed audio 765. In some embodiments, the DAC 770 is configured to convert the equalized audio 755 (or the further processed audio 765) to an analog signal to be provided to the amplifier 780.

FIG. 7B is a block diagram of another example playback device 700B configured in accordance with aspects of the disclosed technology. In this example, the predictive power model 740 and the dynamic equalizer 750 are shown as being integrated with the processor 760. For example, the processor may be configured to execute program instructions stored in at least one non-transitory computer-readable medium (not shown) such that the processor performs the functions of the predictive power model 740 and the dynamic equalizer 750 (e.g., along with any other suitable audio processing and playback functions).

It should be appreciated that other embodiments are possible. For example, in some embodiments, predictive power model 740 and/or the dynamic equalizer 750 may be implemented in software that is executed by a DSP which may be a dedicated or standalone IC, or which may be integrated into the amplifier or other components of the playback device. In some embodiments, the predictive power model 740 and/or the dynamic equalizer 750 may be implemented wholly or partially in the analog domain using analog components.

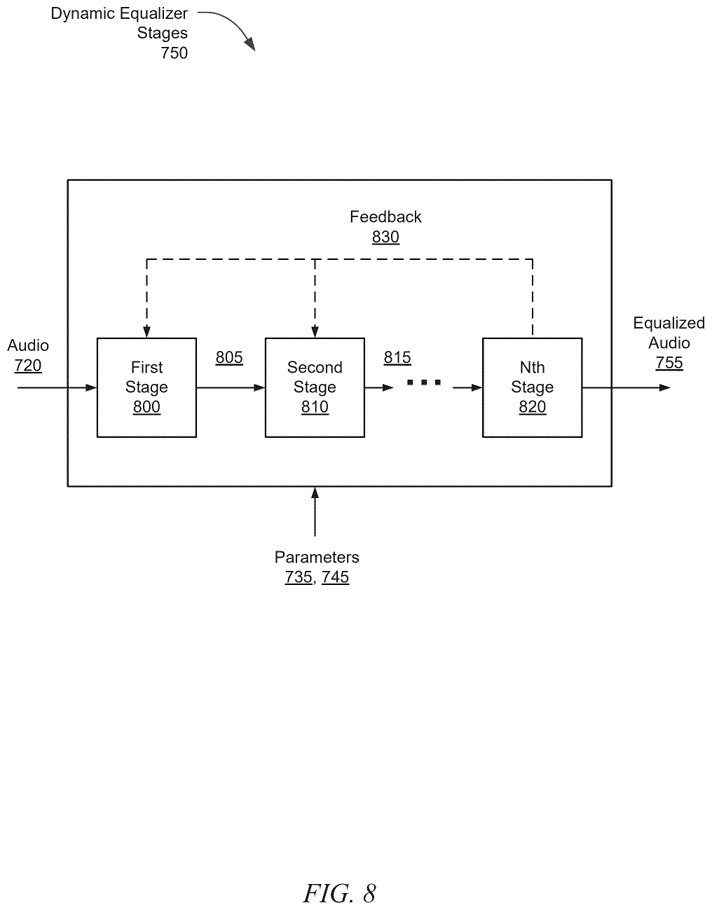

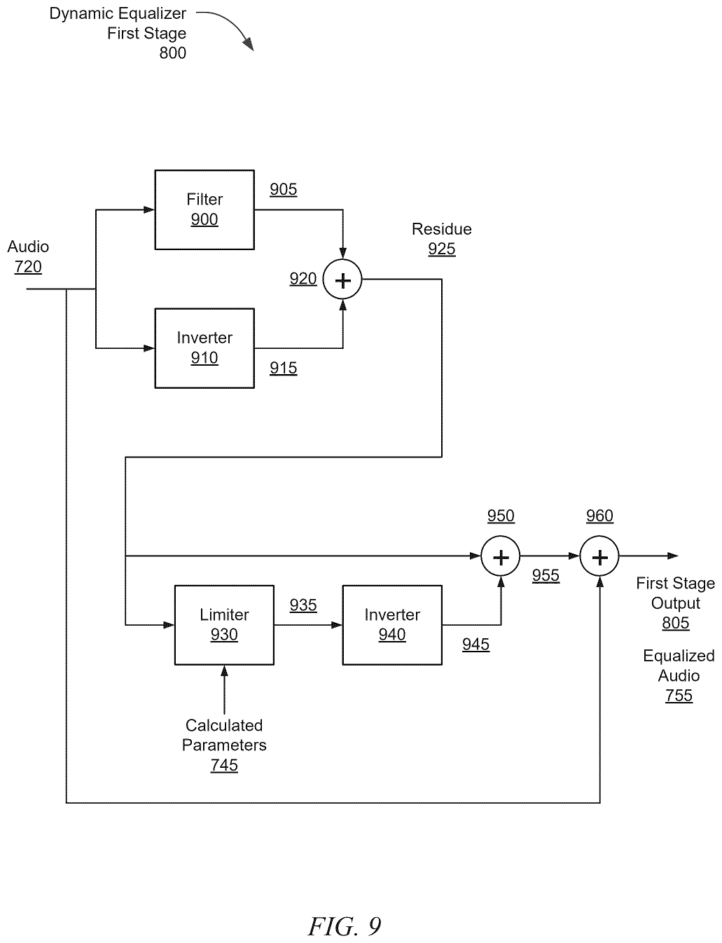

FIG. 8 is a block diagram of an example dynamic equalizer implemented as a cascade of filter stages. In some embodiments, the first stage 810 is configured to employ a notch filter to reduce low frequency content, as explained in greater detail below in connection with FIG. 9. The degree of attenuation applied by the notch filter is based on the power budget (e.g., the calculated parameters 745), with the goal of fitting the signal within the estimated power budget. Although the reduction of low-frequency audio content may need to be engaged for longer periods of time (e.g., entire tracks/albums played at high volume levels), the effects are less noticeable than attenuation applied over a wider spectrum.

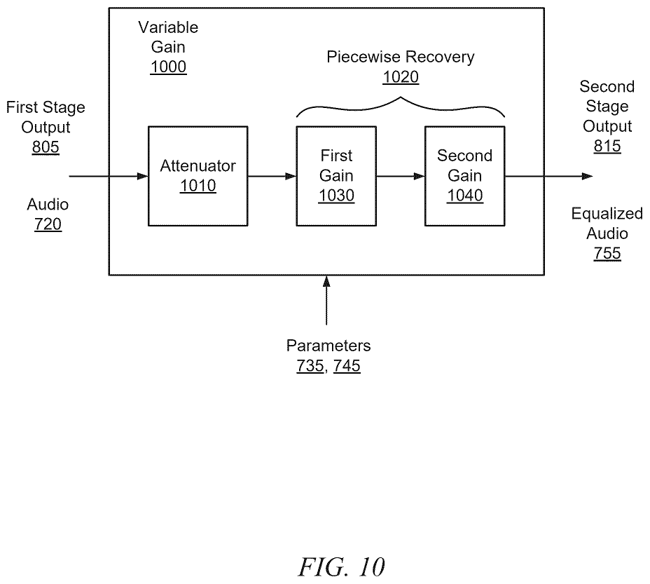

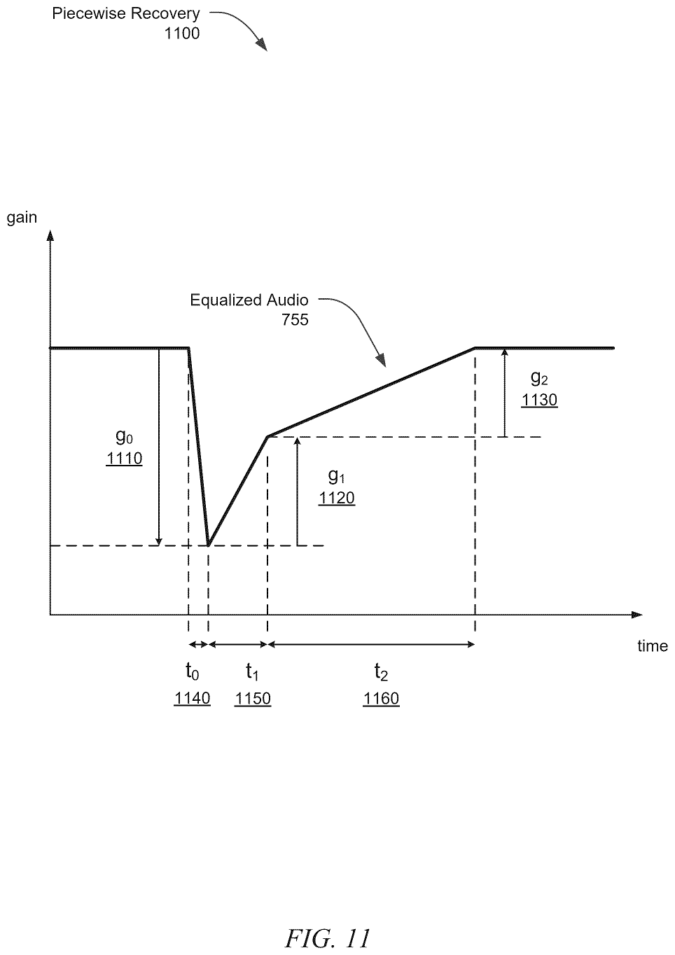

In some embodiments, the second stage 820 is configured to apply additional attenuation to the output 805 of the first stage to generate an output 815 that, in the case of a two stage equalizer, represents the equalized audio 755. This additional attenuation is applied over a broader frequency range, but for shorter durations, as needed, for example, during the hit of a snare drum or other high energy audio event. In some examples, the broader frequency range may comprise the entire frequency spectrum, meaning that the attenuation is essentially a reduction in volume. Since this form of attenuation is more significant/noticeable, it is implemented with a piecewise recovery to mitigate the impact on the user's listening experience, as explained in greater detail below in connection with FIGS. 10 and 11.

In some embodiments, a determination of the need for volume reduction by the second stage 810, and the amount of volume reduction to be provided, is based on the predicted state of the energy storage device 732. For example, the second stage is may be employed to temporarily reduce power consumption if the difference between the current required power (or the power about to be required) and the modeled power for the interface 710 (provided by the model 740) exceeds the stored energy of the energy storage device 732. For example, there may be a hit of a snare drum coming up while the voltage across the power supply capacitors is already near the lower limit due to a prior segment of bass-heavy audio.

Although it is desirable to avoid use of the second stage, since it is more noticeable, there may be times when it is needed, for example due to imperfect power budget estimation provided to the first stage. In these instances, it is preferable to reduce the volume temporarily rather than risk having the playback device reboot due to low voltage, for example.

In some embodiments, additional stages (e.g., up to an Nth stage 820) may be employed. For example, an additional stage 820 may operate on the output 815 of the second stage 810 to generate the equalized audio 755. In some examples, feedback may be provided between the stages. For instance, if the volume needs to be reduced significantly and/or repeatedly in the second stage, that information may be used as feedback to the first stage to intensify the notch filter to provide more attenuation of the low-frequency content which may reduce the number of activations of the later stages.

In some embodiments, the equalizer 750 may be implemented using just one stage, for example either the first stage 800 or the second stage 810.

FIG. 9 is a block diagram of an example first filter stage 800 of the dynamic equalizer 750 configured in accordance with aspects of the disclosed technology. The dynamic equalizer filter stage 800 is shown to include a filter 900, a first signal inverter 910, a first summer 920, a limiter 930, a second signal inverter 940, a second summer 950, and a third summer 960.

In some embodiments, the filter stage 800 is configured to attenuate a spectral region of the audio 720 to generate a filter audio signal 905. The spectral region for attenuation may be selected to match a range of audio frequencies in which significant energy is consumed, which is typically in the bass frequencies that are reproduced by the woofer. In some examples, the filter 900 is a notch filter. In some examples, a center frequency of the notch filter is in a range of 60 Hertz (Hz) to 100 Hz.

In some embodiments, the first signal inverter 910 is configured to invert the audio signal 720 to generate an inverted audio signal 915 and the first summer 920 is configured to sum the filtered audio signal 905 with the inverted audio signal 915 to generate a residue signal 925. The residue signal 925 is the difference between the filtered audio signal 905 and the audio signal 720.

In some embodiments, the limiter 930 is configured to multiply the filter residue 925 by a time varying scale factor that can range from zero to one, when the equalizer is being employed, as based on the calculated parameters 745. When the scale factor is one, the limiter is effectively turned off because the limiter output 935 equals the residue 925 (e.g., the limiter output is a pass through of the limiter input). When the scale factor is zero, the limiter is fully turned on and the limiter output 935 is zero.

The second signal inverter 940 is configured to invert the limiter output 935 to generate an inverted limiter output 945. The inverted limiter output 945 is fed to the second summer 950 for summation with the residue 925 to generate a limited residue signal 955. As such, when the limiter scale factor is one (e.g., the limiter is turned off), the following are true: the limiter output 935 equals the residue 925; the inverted limiter output 945 is the inverse of the residue 925; and the limited residue signal 955 is zero. In this case the third summer 960 adds zero (e.g., the limited residue signal 955) to the audio 720 to generate an output of the dynamic equalizer (e.g., equalized audio 755) that is unchanged from the audio input 720. In other words, when the limiter is turned off, the equalized audio 755 is unchanged from the input audio 720.

At the other range of limiter operation, when the limiter scale factor is zero (e.g., the limiter is fully turned on), the following is true: the limiter output 935 is zero; the inverted limiter output 945 is zero; and the limited residue signal 955 equals the full residue signal 925. In this case the third summer 960 adds the full residue signal 925 to the audio 720 to generate an output of the dynamic equalizer (e.g., equalized audio 755) that is a fully filtered version of the audio input 720.

FIG. 10 is a block diagram of another example filter stage 810 of the dynamic equalizer 750 configured in accordance with aspects of the disclosed technology. The dynamic equalizer filter stage 810 is shown to include a variable gain module that comprises attenuation 1010 and piecewise recovery 1020. The piecewise recovery is implemented as a first gain 1030 followed by a second gain 1040. The operations of attenuation 1010 and piecewise recovery are illustrated in FIG. 11 and described more fully in connection with that Figure. The energy storage state and prediction of upcoming power requirements, as provided by measured parameters 735 and calculated parameters 745, is used to determine whether and how much attenuation to apply at the second stage.

FIG. 11 is a graph illustrating attenuation and piecewise recovery 1100 of the equalized audio, in accordance with aspects of the disclosed technology. In some instances, the gain reduction required to avoid distortion may need to be significant (e.g., a 6 dB reduction), in which case a constant slope recovery may cause the volume reduction to be noticeable to the user (e.g., because it may take multiple seconds to fully recover). To mitigate this issue, the gain recovery may be implemented as a piecewise function, as shown in FIG. 11, that varies based on the attenuation. For example, when the second stage 810 of the dynamic equalizer is activated, an attenuation is applied to the audio signal over a relatively short time period t₀ 1140. The attenuation is shown as gain g₀ 1110, which is a negative gain. A piecewise recovery from the attenuation is then implemented by applying a first gain g₁ 1120 over time period t₁ 1150, followed by a second gain g₂ 1130 over time period t₂ 1160. As shown in this example, the first portion of the gain is recovered quickly during period t₁ 1150 while the second portion of the gain is recovered more slowly over period t₂ 1160 (which may be multiple times longer than t₁). The applied attenuation and subsequent piecewise recovery produce the equalized audio signal 755.

In some embodiments, the first gain g₁ 1120 may be applied linearly over the time period t₁ 1150, as shown. In some other embodiments, the first gain g₁ 1120 may be applied exponentially over the time period t₁ 1150, for example causing the equalized audio to increase more rapidly at the beginning of the time period and more slowly toward the end of the time period. In some embodiments, the second gain g₂ 1130 may be applied linearly over the time period t₂ 1160, as shown. In some other embodiments, the second gain g₂ 1130 may be applied exponentially over the time period t₂ 1160.

In some embodiments, the attenuation (e.g., g₀ 1110) may be in the range of 3 dB to 6 dB, the first gain g₁ 1120 may be in the range of 1 dB to 4 dB, and the second gain g₂ 1130 may be in the range of 1 dB to 4 dB.

In some embodiments, the second time period t₂ 1160 is longer than the first time period t₁ 1150 and the attenuation time period t₀ 1140 is shorter than both the first time period and the second time period. In some embodiments, the first time period t₁ 1150 is in a range of 40 ms to 60 ms and the second time period t₂ 1160 is a range of one second to two seconds.

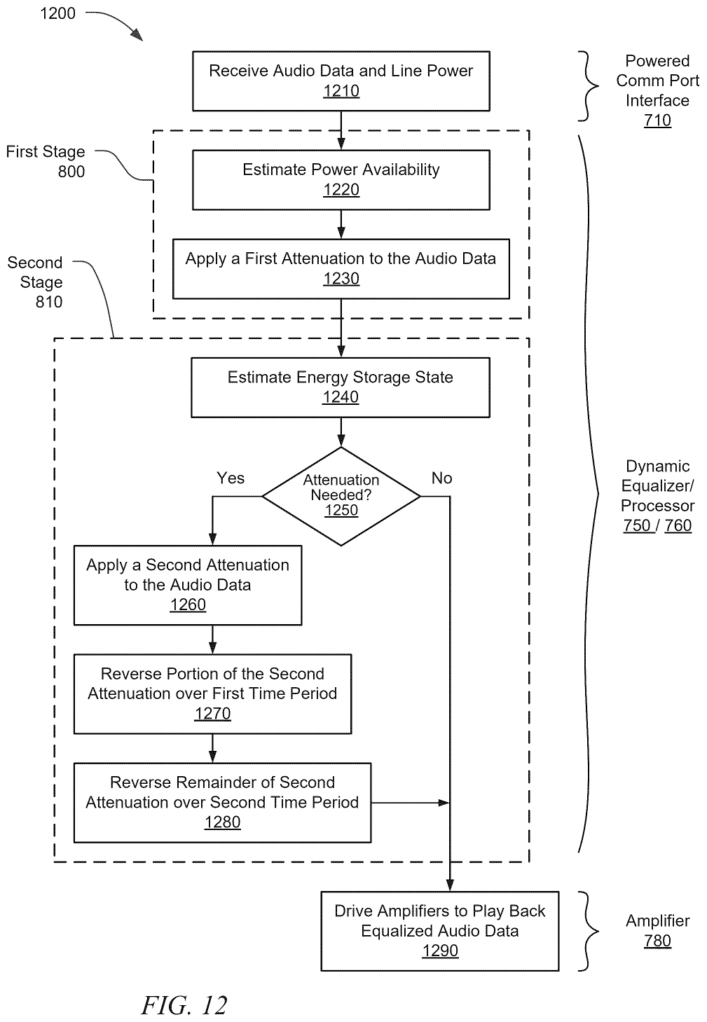

FIG. 12 is a flowchart illustrating an example method 1200 for employing dynamic equalization for power management of a playback device.

Method 1200 commences at block 1210, which includes receiving audio data and line power from a powered communication port of the playback device. In some embodiments, the powered communication port may be a PoE interface.

At block 1220, the method 1200 further includes estimating power availability. In some examples, power availability may include a power budget which is based at least in part on the specification associated with the powered communication port.

At block 1230, the method 1200 further includes applying a first attenuation to the audio data, for example based on the estimated power availability. In some examples, the first attenuation is performed on a spectral region of the audio data, for example at lower frequencies associated with greater energy consumption. In some embodiments, a notch filter is employed to perform the attenuation on the spectral region of the audio data. In some examples, the center frequency of the notch filter is in the range of 60 Hz to 100 Hz, and the attenuation is in the range of 3 dB to 6 dB. In some instances, the first attenuation may be applied for relatively long periods of time, possibly for entire musical tracks and/or albums when played at high volumes. In some embodiments, the operation of block 1230 is performed by the first stage 800 of the dynamic equalizer 750.

At block 1240, the method 1200 further includes estimating an energy storage state. In some examples, the energy storage state may include the voltage of at least one capacitor of the power supply circuitry.

At block 1250, the method 1200 further includes determining if additional attenuation is needed based on at least the energy storage state. In some embodiments, the determination is also based on a prediction of power demand associated with the audio data, and in particular, the segment of audio data about to be played. For example, if a snare drum hit is about to be played, a brief attenuation may be applied to avoid a total discharge of the energy storage device. If additional attenuation is needed the method continues at block 1260, otherwise the method proceeds to block 1290.

At block 1260, the method 1200 further includes applying a second attenuation to the audio data. The second attenuation is applied for a relatively brief time period, as explained previously in connection with the description of FIG. 11.

At block 1270, the method 1200 further includes reversing a portion of the second attenuation over a first time period. In some examples, a first gain is applied to reverse a portion of the attenuation over the first time period subsequent to the attenuation, as previously described.

At block 1280, the method 1200 further includes reversing the remainder of the second attenuation over a second time period. In some examples, a second gain is applied to reverse the remainder of the attenuation over the second time period subsequent to the first time period, to generate equalized audio data, as previously described.

In some embodiments, the operations of blocks 1250 through 1280 are performed by the second (or subsequent) stages 810, . . . 820 of the dynamic equalizer 750.

At block 1290, the method 1200 further includes driving one or more amplifiers of the playback device to play back at least a portion of the equalized audio data through one or more speakers.

### V. Conclusion

The above discussions relating to playback devices, controller devices, playback zone configurations, and media content sources provide only some examples of operating environments within which functions and methods described herein may be implemented. Other operating environments and configurations of media playback systems, playback devices, and network devices not explicitly described herein may also be applicable and suitable for implementation of the functions and methods.

The description above discloses, among other things, various example systems, methods, apparatus, and articles of manufacture including, among other components, firmware and/or software executed on hardware. It is understood that such examples are merely illustrative and should not be considered as limiting. For example, it is contemplated that any or all of the firmware, hardware, and/or software aspects or components can be embodied exclusively in hardware, exclusively in software, exclusively in firmware, or in any combination of hardware, software, and/or firmware. Accordingly, the examples provided are not the only ways to implement such systems, methods, apparatus, and/or articles of manufacture.

Additionally, references herein to “embodiment” means that a particular feature, structure, or characteristic described in connection with the embodiment can be included in at least one example embodiment of an invention. The appearances of this phrase in various places in the specification are not necessarily all referring to the same embodiment, nor are separate or alternative embodiments mutually exclusive of other embodiments. As such, the embodiments described herein, explicitly and implicitly understood by one skilled in the art, can be combined with other embodiments.

The specification is presented largely in terms of illustrative environments, systems, procedures, steps, logic blocks, processing, and other symbolic representations that directly or indirectly resemble the operations of data processing devices coupled to networks. These process descriptions and representations are typically used by those skilled in the art to most effectively convey the substance of their work to others skilled in the art. Numerous specific details are set forth to provide a thorough understanding of the present disclosure. However, it is understood to those skilled in the art that certain embodiments of the present disclosure can be practiced without certain, specific details. In other instances, well known methods, procedures, components, and circuitry have not been described in detail to avoid unnecessarily obscuring aspects of the embodiments. Accordingly, the scope of the present disclosure is defined by the appended claims rather than the foregoing description of embodiments.

When any of the appended claims are read to cover a purely software and/or firmware implementation, at least one of the elements in at least one example is hereby expressly defined to include a tangible, non-transitory medium such as a memory, DVD, CD, Blu-ray, and so on, storing the software and/or firmware.

### VII. Example Features

The following examples pertain to further embodiments, from which numerous permutations and configurations will be apparent.

(Feature 1) A playback device comprising: at least one powered communication port configured to receive audio data and line power; one or more amplifiers configured to drive one or more speakers, the one or more amplifiers having a peak power consumption that is greater than a maximum power of the line power; power supply circuitry comprising at least one capacitor; an equalizer configured to: perform an attenuation on a spectral region of the audio data based on voltage of the at least one capacitor; apply a first gain to reverse a portion of the attenuation over a first time period subsequent to the attenuation; and apply a second gain to reverse a remainder of the attenuation over a second time period subsequent to the first time period, to generate equalized audio data; at least one processor; and at least one non-transitory computer-readable medium comprising program instructions that are executable by the at least one processor such that the playback device is configured to drive the one or more amplifiers to play back at least a portion of the equalized audio data.

(Feature 2) The playback device of feature 1, wherein the equalizer is configured to perform the attenuation further based on a power budget, the power budget based at least in part on the at least one powered communication port.

(Feature 3) The playback device of feature 1, wherein the equalizer is configured to perform the attenuation further based on a prediction of power demand associated with the audio data.

(Feature 4) The playback device of feature 1, wherein the equalizer is configured to perform the attenuation further based on electroacoustic properties of the one or more speakers.

(Feature 5) The playback device of feature 1, wherein the first time period is in a range of 40 milliseconds (ms) to 60 ms and the second time period is in a range of one second to two seconds.

(Feature 6) The playback device of feature 1, wherein the equalizer is configured to perform the attenuation during an attenuation time period and the attenuation time period is shorter than both the first time period and the second time period.

(Feature 7) The playback device of feature 1, wherein the equalizer is configured to increase the first gain linearly over the first time period.

(Feature 8) The playback device of feature 1, wherein the equalizer is configured to increase the first gain exponentially over the first time period.

(Feature 9) The playback device of feature 1, wherein the equalizer is configured to increase the second gain linearly over the second time period.

(Feature 10) The playback device of feature 1, wherein the equalizer is configured to increase the second gain exponentially over the second time period.

(Feature 11) The playback device of feature 1, wherein the equalizer comprises a notch filter configured to perform the attenuation.

(Feature 12) The playback device of feature 11, wherein a center frequency of the notch filter is in a range of 60 Hertz (Hz) to 100 Hz.

(Feature 13) The playback device of feature 1, wherein the at least one powered communication port comprises a power over Ethernet (POE) port or a power over Ethernet plus (PoE+) port.

(Feature 14) The playback device of feature 1, wherein the attenuation is in a range of 3 decibels (dB) to 6 dB, the first gain is in a range of 1 dB to 4 dB, and the second gain is in a range of 1 dB to 4 dB.

(Feature 15) The playback device of feature 1, wherein the equalizer is implemented in a digital signal processor (DSP).

(Feature 16) The playback device of feature 15, wherein the DSP is integrated into the one or more amplifiers.

(Feature 17) A playback device comprising: at least one powered communication port configured to receive audio data and line power; one or more amplifiers configured to drive one or more speakers, the one or more amplifiers having a peak power consumption that is greater than a maximum power of the line power; power supply circuitry comprising at least one capacitor; an equalizer configured to: at least one processor; and at least one non-transitory computer-readable medium comprising program instructions that are executable by the at least one processor such that the playback device is configured to: implement an equalizer to perform an attenuation on a spectral region of the audio data based on voltage of the at least one capacitor, apply a first gain to reverse a portion of the attenuation over a first time period subsequent to the attenuation, and apply a second gain to reverse a remainder of the attenuation over a second time period subsequent to the first time period, to generate equalized audio data; and drive the one or more amplifiers to play back at least a portion of the equalized audio data.

(Feature 18) The playback device of feature 17, wherein the equalizer is configured to perform the attenuation further based on a power budget, the power budget based at least in part on the at least one powered communication port.

(Feature 19) The playback device of feature 17, wherein the equalizer is configured to perform the attenuation further based on a prediction of power demand associated with the audio data.

(Feature 20) The playback device of feature 17, wherein the equalizer is configured to perform the attenuation further based on electroacoustic properties of the one or more speakers.

(Feature 21) The playback device of feature 17, wherein the second time period is longer than the first time period.

(Feature 22) A method for operating a playback device, the method comprising: receiving audio data and line power from a powered communication port of the playback device; performing an attenuation on a spectral region of the audio data based on voltage of at least one capacitor of a power supply circuit of the playback device; applying a first gain to reverse a portion of the attenuation over a first time period subsequent to the attenuation; applying a second gain to reverse a remainder of the attenuation over a second time period subsequent to the first time period, to generate equalized audio data; and driving one or more amplifiers of the playback device to play back at least a portion of the equalized audio data through one or more speakers.

(Feature 23) The method of feature 22, further comprising performing the attenuation based on a power budget, the power budget based at least in part on the powered communication port.

(Feature 24) The method of feature 22, further comprising performing the attenuation based on a prediction of power demand associated with the audio data.

(Feature 25) The method of feature 22, further comprising performing the attenuation based on electroacoustic properties of the one or more speakers.

(Feature 26) The method of feature 22, wherein the second time period is longer than the first time period.

(Feature 27) The method of feature 22, wherein the first time period is in a range of 40 milliseconds (ms) to 60 ms and the second time period is in a range of one second to two seconds.

(Feature 28) The method of feature 22, further comprising performing the attenuation during an attenuation time period and the attenuation time period is shorter than both the first time period and the second time period.

(Feature 29) The method of feature 22, further comprising increasing the first gain linearly over the first time period.

(Feature 30) The method of feature 22, further comprising increasing the first gain exponentially over the first time period.

(Feature 31) The method of feature 22, further comprising increasing the second gain linearly over the second time period.

(Feature 32) The method of feature 22, further comprising increasing the second gain exponentially over the second time period.

(Feature 33) The method of feature 22, further comprising employing a notch filter to perform the attenuation.

(Feature 34) The method of feature 33, wherein a center frequency of the notch filter is in a range of 60 Hertz (Hz) to 100 Hz.

(Feature 35) The method of feature 23, wherein the powered communication port comprises a power over Ethernet (POE) port or a power over Ethernet plus (PoE+) port.

(Feature 36) The method of feature 23, wherein the attenuation is in a range of 3 decibels (dB) to 6 dB, the first gain is in a range of 1 dB to 4 dB, and the second gain is in a range of 1 dB to 4 dB.

What is claimed is:

1. A playback device comprising:
at least one powered communication port configured to receive audio data and line power;
one or more amplifiers configured to drive one or more speakers, the one or more amplifiers having a peak power consumption that is greater than a maximum power of the line power;
power supply circuitry comprising at least one capacitor;
an equalizer configured to:
perform an attenuation on a spectral region of the audio data based on voltage of the at least one capacitor;
apply a first gain to reverse a portion of the attenuation over a first time period subsequent to the attenuation; and
apply a second gain to reverse a remainder of the attenuation over a second time period subsequent to the first time period, to generate equalized audio data;
at least one processor; and
at least one non-transitory computer-readable medium comprising program instructions that are executable by the at least one processor such that the playback device is configured to drive the one or more amplifiers to play back at least a portion of the equalized audio data.

2. The playback device of claim 1, wherein the equalizer is configured to perform the attenuation further based on a power budget, the power budget based at least in part on the at least one powered communication port.

3. The playback device of claim 1, wherein the equalizer is configured to perform the attenuation further based on a prediction of power demand associated with the audio data.

4. The playback device of claim 1, wherein the equalizer is configured to perform the attenuation further based on electroacoustic properties of the one or more speakers.

5. The playback device of claim 1, wherein the first time period is in a range of 40 milliseconds (ms) to 60 ms, the second time period is in a range of one second to two seconds, the attenuation is in a range of 3 decibels (dB) to 6 dB, the first gain is in a range of 1 dB to 4 dB, and the second gain is in a range of 1 dB to 4 dB.

6. The playback device of claim 1, wherein the equalizer is configured to perform the attenuation during an attenuation time period and the attenuation time period is shorter than both the first time period and the second time period.

7. The playback device of claim 1, wherein the equalizer is configured to increase the first gain linearly over the first time period or to increase the first gain exponentially over the first time period.

8. The playback device of claim 1, wherein the equalizer is configured to increase the second gain linearly over the second time period or to increase the second gain exponentially over the second time period.

9. The playback device of claim 1, wherein the equalizer comprises a notch filter configured to perform the attenuation, wherein a center frequency of the notch filter is in a range of 60 Hertz (Hz) to 100 Hz.

10. The playback device of claim 1, wherein the at least one powered communication port comprises a power over Ethernet (POE) port or a power over Ethernet plus (PoE+) port.

11. The playback device of claim 1, wherein the equalizer is implemented in a digital signal processor (DSP).

12. The playback device of claim 11, wherein the DSP is integrated into the one or more amplifiers.

13. A playback device comprising:
at least one powered communication port configured to receive audio data and line power;
one or more amplifiers configured to drive one or more speakers, the one or more amplifiers having a peak power consumption that is greater than a maximum power of the line power;
power supply circuitry comprising at least one capacitor;
at least one processor; and
at least one non-transitory computer-readable medium comprising program instructions that are executable by the at least one processor such that the playback device is configured to:
implement an equalizer to
perform an attenuation on a spectral region of the audio data based on voltage of the at least one capacitor,
apply a first gain to reverse a portion of the attenuation over a first time period subsequent to the attenuation, and
apply a second gain to reverse a remainder of the attenuation over a second time period subsequent to the first time period, to generate equalized audio data; and
drive the one or more amplifiers to play back at least a portion of the equalized audio data.

14. The playback device of claim 13, wherein the equalizer is configured to perform the attenuation further based on a power budget, the power budget based at least in part on the at least one powered communication port.

15. The playback device of claim 13, wherein the equalizer is configured to perform the attenuation further based on a prediction of power demand associated with the audio data and based on electroacoustic properties of the one or more speakers.

16. The playback device of claim 13, wherein the second time period is longer than the first time period.

17. A method for operating a playback device, the method comprising:
receiving audio data and line power from a powered communication port of the playback device;
performing an attenuation on a spectral region of the audio data based on voltage of at least one capacitor of a power supply circuit of the playback device;
applying a first gain to reverse a portion of the attenuation over a first time period subsequent to the attenuation;
applying a second gain to reverse a remainder of the attenuation over a second time period subsequent to the first time period, to generate equalized audio data; and
driving one or more amplifiers of the playback device to play back at least a portion of the equalized audio data through one or more speakers.

18. The method of claim 17, further comprising performing the attenuation based on a power budget, the power budget based at least in part on the powered communication port.

19. The method of claim 17, further comprising performing the attenuation based on a prediction of power demand associated with the audio data, and based on electroacoustic properties of the one or more speakers.

20. The method of claim 17, wherein the second time period is longer than the first time period.
